(19) United States
(12) Patent Application Publication
(10) Pub. No.: US 2019/0154891 A1
(43) Pub. Date: May 23, 2019

(54) DRY ETCHING COMPOSITION, KIT, PATTERN FORMATION METHOD, AND METHOD OF MANUFACTURING OPTICAL FILTER

(71) Applicant: FUJIFILM Corporation, Tokyo (JP)

(72) Inventor: Keisuke ARIMURA, Haibara-gun (JP)

(73) Assignee: FUJIFILM Corporation, Tokyo (JP)

(21) Appl. No.: 16/251,429

(22) Filed: Jan. 18, 2019

Related U.S. Application Data
(63) Continuation of application No. PCT/JP2017/033111, filed on Sep. 13, 2017.

(30) Foreign Application Priority Data
Sep. 27, 2016 (JP) 2016-188265

(51) Int. Cl. G02B 5/18; G03F 7/00; G03F 7/20; G03F 7/075

(52) U.S. Cl. CPC G02B 5/1857; G03F 7/0007; G03F 7/0755; G03F 7/0752; G03F 7/2002

(57) ABSTRACT

A dry etching composition includes a coloring material which allows transmission of infrared rays and shields visible light, a curable compound, and a solvent, in which a ratio A/B between a minimum value A of a light absorbance of the composition in a wavelength range of 400 to 700 nm and a maximum value B of a light absorbance in a wavelength range of 1100 to 1300 nm is 4.5 or greater.

### CROSS-REFERENCE TO RELATED APPLICATIONS

This application is a Continuation of PCT International Application No. PCT/JP2017/033111, filed on Sep. 13, 2017, which claims priority under 35 U.S.C. § 119(a) to Japanese Patent Application No. 2016-188265, filed on Sep. 27, 2016. Each of the above application(s) is hereby expressly incorporated by reference, in its entirety, into the present application.

### BACKGROUND OF THE INVENTION

### 1. Field of the Invention

The present invention relates to a dry etching composition which can be used for forming an infrared transmitting filter or the like. In addition, the present invention also relates to a kit, a pattern formation method, and a method of manufacturing an optical filter.

### 2. Description of the Related Art

A solid-state imaging element is utilized as an optical sensor in various applications. For example, since infrared rays have a longer wavelength than visible rays, infrared rays are not easily scattered and can be utilized for distance measurement, three-dimensional measurement, and the like. In addition, since infrared rays are invisible to humans, animals, and the like, infrared rays may be used to take photos of nocturnal wild animals, as well as to photograph an object without irritating the object for security purposes, without being noticed by the object even in a case where the object is illuminated with an infrared light source at nighttime. In this manner, an optical sensor to sense infrared rays (infrared sensor) can be developed for various applications. In recent years, an infrared transmitting filter has been developed.

In addition, an infrared transmitting filter is used with a pattern formed thereon. JP2014-130173A discloses a method of manufacturing an infrared transmitting filter including a step of applying a composition for a color filter to a substrate to form an infrared transmitting composition layer, a step of exposing the infrared transmitting composition layer in a pattern shape, and a step of developing the infrared transmitting composition layer after the exposure to form a pattern.

### SUMMARY OF THE INVENTION

In recent years, further miniaturization of the pattern size in various kinds of optical filters has been carried out. In an infrared transmitting filter, miniaturization of the pattern size has also been studied.

On the other hand, the pattern formation of an infrared transmitting filter has been conventionally carried out by photolithography. However, since the infrared transmitting filter has high visible light shielding properties, the transmittance of light (for example, i-rays) used for exposure is low. Therefore, in the infrared transmitting filter, as the pattern size is miniaturized, the pattern formation tends to become difficult with the photolithography method. For example, since the infrared transmitting filter has a low transmittance of i-rays or the like, in a case where the exposure amount is too small, sufficient light does not reach the lower part (support side) of the film, and the rectangularity of the pattern tends to decrease or the adhesiveness between the pattern and the support tends to decrease. In addition, in a case where the exposure amount is too large, the unexposed portion of the mask peripheral edge is also exposed, and pattern thickening tends to occur easily.

Accordingly, an object of the present invention is to provide a dry etching composition capable of forming a pattern having high visible light shielding properties and having excellent transmittance of infrared rays in a specific wavelength range with good pattern resolution, a kit, a pattern formation method, and a method of manufacturing an optical filter.

As a result of intensive studies conducted by the present inventors, the present inventors have been found that by carrying out pattern formation with a composition in which a ratio A/B between a minimum value A of a light absorbance in a wavelength range of 400 to 700 nm and a maximum value B of a light absorbance in a wavelength range of 1100 to 1300 nm is 4.5 or greater by a dry etching method, it is possible to form a cured film pattern having high visible light shielding properties and having excellent transmittance of infrared rays in a specific wavelength range with good pattern resolution, and thus have completed the present invention. The present invention provides the followings.

<1> A dry etching composition comprising: a coloring material which allows transmission of infrared rays and shields visible light; a curable compound; and a solvent,

in which a ratio A/B between a minimum value A of a light absorbance of the composition in a wavelength range of 400 to 700 nm and a maximum value B of a light absorbance in a wavelength range of 1100 to 1300 nm is 4.5 or greater.

<2> The dry etching composition according to <1>, in which the curable compound includes a compound having at least one selected from the group consisting of a group having an ethylenically unsaturated bond, an epoxy group, and an alkoxysilyl group.

<3> The dry etching composition according to <1>, in which the curable compound includes a compound having an epoxy group.

<4> The dry etching composition according to any one of <1> to <3>, in which the curable compound includes a resin A,

the resin A includes a resin A1 having a crosslinkable group, and a resin A2 having an acid group, and

a sum of a crosslinkable group value and an acid value of the resin A is 0.1 to 10.0 mmol/g.

<5> The dry etching composition according to <4>, in which the resin A1 is a resin having an epoxy group.

<6> The dry etching composition according to <5>, in which an epoxy group value a1 of the resin A1 is 0.1 to 9.9 mmol/g, and an acid value a2 of the resin A2 is 0.1 to 9.9 mmol/g.

<7> The dry etching composition according to any one of <1> to <6>, in which the coloring material which allows transmission of infrared rays and shields visible light includes an organic pigment.

<8> The dry etching composition according to any one of <1> to <7>, in which the coloring material which allows transmission of infrared rays and shields visible light includes two or more selected from the group consisting of a red pigment, a blue pigment, a yellow pigment, a violet pigment, and a green pigment.

<9> A kit comprising: the dry etching composition according to any one of <1> to <8>; and an infrared absorbing composition for photolithography including an infrared absorber.

<10> A pattern formation method comprising: forming a composition layer on a support using the dry etching composition according to any one of <l> to <8>; and

patterning the composition layer by a dry etching method.

<11> The pattern formation method according to <10>, further comprising: forming an infrared absorbing composition layer on the support using an infrared absorbing composition including an infrared absorber after the patterning of the composition layer by the dry etching method; and

patterning the infrared absorbing composition layer by photolithography.

<12> The pattern formation method according to <11>, further comprising: forming a coloring composition layer on the infrared absorbing composition layer using a coloring composition including a chromatic colorant after the patterning of the infrared absorbing composition layer by photolithography; and

patterning the coloring composition layer by photolithography.

<13> A method of manufacturing an optical filter comprising:

the pattern formation method according to any one of <10> to <12>.

According to the present invention, it is possible to provide a dry etching composition capable of forming a pattern having high visible light shielding properties and having excellent transmittance of infrared rays in a specific wavelength range with good pattern resolution, a kit, a pattern formation method, and a method of manufacturing an optical filter.

### BRIEF DESCRIPTION OF THE DRAWINGS

FIG. 1 is a schematic cross-sectional view showing a configuration of an embodiment of an infrared sensor.

### DESCRIPTION OF THE PREFERRED EMBODIMENTS

In the present specification, the total solid content means the total mass of components obtained by removing a solvent from the entire composition.

In the present specification, regarding the denoting of a group (atomic group), a group not denoted with “substituted” or “unsubstituted” includes both a group (atomic group) having no substituents and a group (atomic group) having a substituent. For example, an “alkyl group” includes not only an alkyl group (unsubstituted alkyl group) having no substituents but also an alkyl group (substituted alkyl group) having a substituent.

In the present specification, unless otherwise specified, the term “exposure” includes not only exposure using light but also drawing by a particle ray such as an electron beam or an ion beam. In addition, examples of light used in exposure include actinic light such as a bright line spectrum of a mercury lamp, a far ultraviolet ray represented by an excimer laser, an extreme ultraviolet ray (EUV light), an X-ray, or an electron beam, or radiation.

In the present specification, the term “(meth)acrylate” represents both or either of acrylate and methacrylate, the term “(meth)allyl” represents both or either of allyl or methallyl, the term “(meth)acryl” represents both or either of acryl and methacryl, and the term “(meth)acryloyl” represents both or either of acryloyl and methacryloyl.

In the present specification, the term “step” includes not only an independent step but also a step that cannot be clearly distinguished from other steps as long as the intended object thereof is achieved.

In the present specification, the weight-average molecular weight and the number average molecular weight are defined as values in terms of polystyrene as measured by gel permeation chromatography (GPC). In the present specification, for example, the weight-average molecular weight (Mw) and the number average molecular weight (Mn) can be obtained using HLC-8220 (manufactured by Tosoh Corporation), TSKgel Super AWM-H (6.0 mm ID (inner diameter)×15.0 cm, manufactured by Tosoh Corporation) as a column, and 10 mmol/L of a lithium bromide N-methyl pyrrolidinone (NMP) solution as an eluant.

<Composition>

A composition (dry etching composition) according to an embodiment of the present invention is a composition including a coloring material which allows transmission of infrared rays and shields visible light, a curable compound, and a solvent,

in which a ratio A/B between a minimum value A of a light absorbance of the composition in a wavelength range of 400 to 700 nm and a maximum value B of a light absorbance in a wavelength range of 1100 to 1300 nm is 4.5 or greater.

Since the ratio A/B between the minimum value A of a light absorbance in a wavelength range of 400 to 700 nm and the maximum value B of a light absorbance in a wavelength range of 1100 to 1300 nm is 4.5 or greater in the composition according to the embodiment of the present invention, it is possible to form a film capable of shielding visible light and allowing transmission of infrared rays in a specific wavelength range. By forming a pattern by a dry etching method using this composition, even in a case where high resolution is achieved, a pattern having good adhesiveness with a support and excellent rectangularity can be formed. Therefore, according to the present invention, it is possible to form a pattern having high visible light shielding properties and excellent transmittance of infrared rays in a specific wavelength range with good resolution.

In the composition according to the embodiment of the present invention, regarding the conditions of the light absorbance, the conditions of the light absorbance can be suitably achieved by, for example, adjusting the kind of the coloring material which allows transmission of infrared rays and shields visible light, and the amount thereof.

Regarding the spectral characteristics of the composition according to the embodiment of the present invention, the value of the above ratio A/B is preferably 5 or more, more preferably 7 or more, even more preferably 7.5 or more, particularly preferably 15 or more, and most preferably 30 or more.

A light absorbance Aλ at a certain wavelength λ is defined by Equation (1).

Aλ=−log(T/100) (1)

Aλ is a light absorbance at a wavelength λ and Tλ is a transmittance (%) at a wavelength λ.

In the present invention, a value of the light absorbance may be a value measured in the state of a solution or a value of a film which is formed using the composition. In a case where the light absorbance is measured in a state of the film, the light absorbance is preferably measured using a film prepared by applying the composition to a glass substrate by a method such as spin coating so that the thickness of the film after drying becomes a predetermined thickness, and drying the composition at 100° C. for 120 seconds using a hot plate. The thickness of the film can be obtained by measuring the thickness of the substrate having the film using a stylus surface profilometer (DEKTAK 150, manufactured by ULVAC Inc.).

In addition, the light absorbance can be measured using a spectrophotometer known in the related art. The measurement conditions for the light absorbance are not particularly limited, but it is preferable that the maximum value B of the light absorbance at a wavelength in a range of 1100 nm to 1300 nm is measured under conditions which are adjusted such that the minimum value A of the light absorbance at a wavelength in a range of 400 nm to 700 nm is 0.1 to 3.0. By measuring the light absorbance under such the conditions, a measurement error can be further reduced. A method of adjusting the minimum value A of the light absorbance in a wavelength range of 400 nm to 700 nm to be 0.1 to 3.0 is not particularly limited. For example, in a case where the light absorbance is measured in the state of the composition, for example, a method of adjusting the optical path length of a sample cell can be used. In addition, in a case where the light absorbance is measured in the state of the film, for example, a method of adjusting the thickness of the film can be used.

Specific examples of methods of measuring the spectral characteristics, the film thickness, and the like of the film formed using the composition according to the embodiment of the present invention are as follows.

The composition according to the embodiment of the present invention is applied to a glass substrate using a method such as spin coating such that the thickness of the film after drying is a predetermined film thickness, and then dried at 100° C. for 120 seconds using a hot plate. The thickness of the film is obtained by measuring the thickness of the substrate having the film after drying using a stylus surface profilometer (DEKTAK 150, manufactured by ULVAC Inc.). The transmittance of the substrate having the film after drying is measured in a wavelength range of 300 to 1300 nm, using a spectrophotometer of an ultraviolet-visible-near-infrared spectrophotometer (U-4100, manufactured by Hitachi High-Technologies Corporation).

The composition according to the embodiment of the present invention also referred to as an infrared transmitting composition since the composition allows transmission of infrared rays. Hereinafter, each component constituting the composition according to the embodiment of the present invention will be described.

<<Coloring Material which Allows Transmission of Infrared Rays and Shields Visible Light>>

The composition according to the embodiment of the present invention contains a coloring material which allows transmission of infrared rays and shields visible light (hereinafter, also referred to as a coloring material which shields visible light).

In the present invention, the coloring material which shields visible light is preferably a coloring material which absorbs light in a wavelength range from violet to red. In addition, in the present invention, the coloring material which shields visible light is preferably a coloring material which shields light in a wavelength range of 400 to 700 nm. In the present invention, the coloring material which shields visible light preferably satisfies at least one of the following requirement (1) or (2).

(1): The material contains two or more kinds of chromatic colorants and forms black in a combination of two or more kinds of chromatic colorants.

(2): The material contains an organic black colorant. In the aspect of (2), it is preferable that the material further contains a chromatic colorant.

In the present invention, the chromatic colorant means a colorant other than a white colorant and a black colorant. The chromatic colorant is preferably a colorant having a maximum absorption wavelength in a wavelength range of 400 to 700 nm. In addition, in the present invention, the organic black colorant as the coloring material which shields visible light means a material that absorbs visible light but allows transmission of at least part of infrared rays. Accordingly, in the present invention, the organic black colorant as the coloring material which shields visible light does not include a black colorant which absorbs both visible light and infrared rays, for example, carbon black or titanium black. The organic black colorant is preferably a colorant having a maximum absorption wavelength in a wavelength range of 400 to 700 nm.

In the present invention, in the coloring material which shields visible light, for example, a ratio A1/B1 between a minimum value A1 of a light absorbance in a wavelength range of 400 to 700 nm and a minimum value B1 of a light absorbance in a wavelength range of 900 to 1300 nm is preferably 4.5 or greater. In addition, in the present invention, the coloring material which shields visible light is preferably a coloring material which allows transmission of at least part of light in a wavelength range of 800 to 1300 nm.

The above characteristic may be satisfied with one kind of material or may be satisfied with a combination of a plurality of materials. For example, in a case of the aspect of (1), it is preferable that a plurality of chromatic colorants are combined to satisfy the above spectral characteristics. In addition, in a case of the aspect of (2), the organic black colorant may satisfy the above spectral characteristics. Further, the organic black colorant and the chromatic colorant may be combined to satisfy the above spectral characteristics.

(Chromatic Colorant)

In the present invention, the chromatic colorant is preferably a colorant selected from a red colorant, a green colorant, a blue colorant, a yellow colorant, a violet colorant, and an orange colorant.

In the present invention, the chromatic colorant may be a pigment or a dye. Preferably, the chromatic colorant is a pigment.

An average particle diameter (r) of the pigment preferably satisfies 20 nm≤r≤300 nm, more preferably satisfies 25 nm≤r≤250 nm, and particularly preferably satisfies 30 nm≤r≤200 nm. The term “average particle diameter” used herein means the average particle diameter of secondary particles in which the primary particles of the pigment are aggregated.

In addition, regarding the particle size distribution of the secondary particles of the pigment that can be used (hereinafter, also simply referred to as “particle size distribution”), the particle size distribution of the secondary particles in a range of (average particle diameter ±100) nm is 70% by mass or more and preferably 80% by mass or more. The particle size distribution of the secondary particles can be measured using a scattering intensity distribution.

The pigment having the above-described average particle diameter and particle size distribution can be prepared by mixing and dispersing a commercially available pigment with another pigment (in which the average particle diameter of the secondary particles is typically more than 300 nm) that is used depending on the situation, preferably as a pigment mixed liquid obtained by mixing a resin and an organic solvent, while pulverizing the materials using a pulverizer, for example, a beads mill or a roll mill. The thus-obtained pigment is typically in the form of a pigment dispersion liquid.

The pigment is preferably an organic pigment and examples thereof include the following pigments. However, the present invention is not limited to these examples:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and the like (all of which are red pigments);

C.I. Pigment Green 7, 10, 36, 37, 58, 59, and the like (all of which are green pigments);

C.I. Pigment Violet 1, 19, 23, 27, 32, 37, 42, and the like (all of which are violet pigments);

C.I. Pigment Blue 1, 2, 15, 15:1, 15:2, 15:3, 15:4, 15:6, 16, 22, 60, 64, 66, 79, 80, and the like (all of which are blue pigments); and

These organic pigments can be used alone or in combination of various pigments.

The dye is not particularly limited and known dyes can be used. As the chemical structure, it is possible to use dyes such as pyrazole azo-based, anilino azo-based, triphenylmethane-based, anthraquinone-based, anthrapyridone-based, benzylidene-based, oxonol-based, pyrazolotriazole azo-based, pyridone azo-based, cyanine-based, phenothiazino-based, pyrrolopyrazole azomethine-based, xanthene-based, phthalocyanine-based, benzopyran-based, indigo-based, and pyrromethene-based dyes. Further, multimers of these dyes can also be used. In addition, dyes described in JP2015-028144A and JP2015-034966A can also be used.

The coloring material which allows transmission of infrared rays and shields visible light in the present invention preferably includes two or more pigments selected from the group consisting of a red pigment, a blue pigment, a yellow pigment, a violet pigment, and a green pigment. That is, it is preferable that the coloring material which allows transmission of infrared rays and shields visible light forms black in combination with two or more pigments selected from the group consisting of a red pigment, a blue pigment, a yellow pigment, a violet pigment, and a green pigment. Examples of preferable combinations include the followings.

(1) An aspect containing a red pigment and a blue pigment;

(2) An aspect containing a red pigment, a blue pigment, and a yellow pigment;

(3) An aspect containing a red pigment, a blue pigment, a yellow pigment, and a violet pigment;

(4) An aspect containing a red pigment, a blue pigment, a yellow pigment, a violet pigment, and a green pigment;

(5) An aspect containing a red pigment, a blue pigment, a yellow pigment, and a green pigment; and

(6) An aspect containing a red pigment, a blue pigment, and a green pigment.

In the aspect of (1), the mass ratio of the red pigment and the blue pigment (red pigment:blue pigment) is preferably 20 to 80:20 to 80, more preferably 20 to 60:40 to 80, and even more preferably 20 to 50:50 to 80.

In the aspect of (2), the mass ratio of the red pigment, the blue pigment, and the yellow pigment (red pigment:blue pigment:yellow pigment) is preferably 10 to 80 20 to 80:10 to 40, more preferably 10 to 60:30 to 80:10 to 30, and even more preferably 10 to 40:40 to 80:10 to 20.

In the aspect of (3), the mass ratio of the red pigment, the blue pigment, the yellow pigment, and the violet pigment (red pigment:blue pigment:yellow pigment:violet pigment) is preferably 10 to 80:20 to 80:5 to 40:5 to 40, more preferably 10 to 60:30 to 80:5 to 30:5 to 30, and even more preferably 10 to 40:40 to 80:5 to 20:5 to 20.

In the aspect of (4), the mass ratio of the red pigment, the blue pigment, the yellow pigment, the violet pigment, and the green pigment (red pigment:blue pigment:yellow pigment:violet pigment:green pigment) is preferably 10 to 80:20 to 80:5 to 40:5 to 40:5 to 40, more preferably 10 to 60:30 to 80:5 to 30:5 to 30:5 to 30, and even more preferably 10 to 40:40 to 80:5 to 20:5 to 20:5 to 20.

In the aspect of (5), the mass ratio of the red pigment, the blue pigment, the yellow pigment, and the green pigment (red pigment:blue pigment:yellow pigment:green pigment) is preferably 10 to 80:20 to 80:5 to 40:5 to 40, more preferably 10 to 60:30 to 80:5 to 30:5 to 30, and even more preferably 10 to 40:40 to 80:5 to 20:5 to 20.

In the aspect of (6), the mass ratio of the red pigment, the blue pigment, and the green pigment (red pigment:blue pigment:green pigment) is preferably 10 to 80:20 to 80:10 to 40, more preferably 10 to 60:30 to 80:10 to 30, and even more preferably 10 to 40:40 to 80:10 to 20.

(Organic Black Colorant)

In the present invention, examples of the organic black colorant include a bisbenzofuranone compound, an azomethine compound, a perylene compound, and an azo-based compound, and a bisbenzofuranone compound and a perylene compound are preferable.

Examples of the bisbenzofuranone compound include compounds described in JP2010-534726A, JP2012-515233A, and JP2012-515234A, and for example, “Irgaphor Black” (manufactured by BASF SE) is available.

Examples of the perylene compound include C.I. Pigment Black 31 and 32.

Examples of the azomethine compound include compounds described in JP1989-170601A (JP-H01-170601A), and JP1990-034664A (JP-H02-034664A). For example, “CHROMOFINE BLACK All1103” (manufactured by Dainichiseika Color & Chemicals Mfg. Co., Ltd.) is available.

The azo compound is not particularly limited, and for example, a compound represented by the following Formula (A-1) can be suitably used.

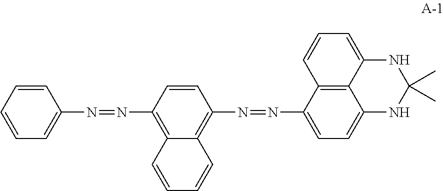 [SMILES: CC1(C)Nc2cccc3c(N=Nc4ccc(N=Nc5ccccc5)c5ccccc45)ccc(c23)N1]

In the present invention, it is preferable that the bisbenzofuranone compound is one of the following compounds represented by the following formulae or a mixture thereof.

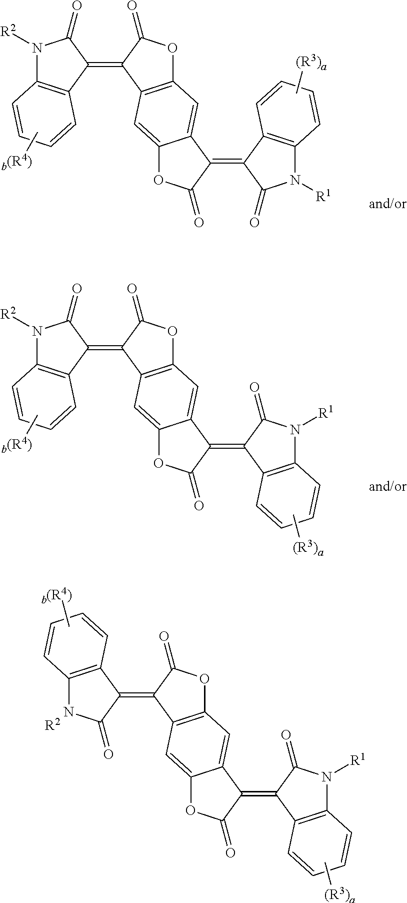

In the formulae, R¹ and R² each independently represent a hydrogen atom or a substituent, R³ and R⁴ each independently represent a substituent, a and b each independently represent an integer of 0 to 4, in a case where a is 2 or more, a plurality of R³'s may be the same as or different from each other, a plurality of R³'s may be bonded to each other to form a ring, in a case where b is 2 or more, a plurality of R⁴'s may be the same as or different from each other, and a plurality of R⁴'s may be bonded to each other to form a ring.

The substituent represented by R¹ to R⁴ is a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸, and R³⁰¹ to R³¹⁸ each independently represent a hydrogen atom, an alkyl group, an alkenyl group, an alkynyl group, an aryl group, or a heteroaryl group.

Regarding the details of the bisbenzofuranone compound, the description of paragraphs 0014 to 0037 of JP2010-534726A can be referred to and the content thereof is incorporated in this specification.

In the present invention, in a case where the organic black colorant is used as the coloring material which shields visible light, it is preferable that the organic black colorant is used in combination of a chromatic colorant. By using the organic black colorant in combination of a chromatic colorant, excellent spectral characteristics are easily obtained. Examples of the chromatic colorant which can be used in combination with the organic black colorant include a red colorant, a blue colorant, and a violet colorant. A red colorant and a blue colorant are preferable. These colorants may be used alone or in combination of two or more kinds thereof.

In addition, regarding the mixing ratio between the chromatic colorant and the organic black colorant, the amount of the chromatic black colorant is preferably 10 to 200 parts by mass and more preferably 15 to 150 parts by mass with respect to 100 parts by mass of the organic black colorant.

In the present invention, it is preferable that the coloring material which shields visible light forms black in combination of two or more kinds of chromatic colorants and oxotitanyl phthalocyanine. The oxotitanyl phthalocyanine is a compound having a maximum absorption wavelength near a wavelength of 830 nm and is one infrared absorber. However, the oxotitanyl phthalocyanine has a maximum absorption wavelength near a wavelength of 650 nm. That is, the oxotitanyl phthalocyanine also has absorption in part of the visible range. Therefore, black can be formed by combining the oxotitanyl phthalocyanine and a chromatic colorant. Examples of the chromatic colorant that is used in combination of the oxotitanyl phthalocyanine include a red colorant, a yellow colorant, and a violet colorant. Examples of preferable combinations include the following (1) and (2).

(1) An aspect in which black is formed by combining oxotitanyl phthalocyanine, a red colorant, and a yellow colorant. The mass ratio of oxotitanyl phthalocyanine:red colorant:yellow colorant is preferably 20 to 70:20 to 50:5 to 30, and the mass ratio of oxotitanyl phthalocyanine:red colorant:yellow colorant is more preferably 30 to 60:25 to 45:10 to 20.

(2) An aspect in which black is formed by combining oxotitanyl phthalocyanine, a red colorant, and a violet colorant. The mass ratio of oxotitanyl phthalocyanine:red colorant:violet colorant is preferably 10 to 50:20 to 50:20 to 50, and the mass ratio of oxotitanyl phthalocyanine:red colorant:violet colorant is more preferably 15 to 45:25 to 45:30 to 45.

In the present invention, the content of the pigment in the coloring material which shields visible light is preferably 95 mass % or more, more preferably 97 mass % or more, and even more preferably 99 mass % or more with respect to the total mass of the coloring material which shields visible light.

In the composition according to the embodiment of the present invention, the content of the coloring material which shields visible light is preferably 40% to 75% by mass with respect to the total solid content of the composition. The upper limit is preferably 70% by mass or less and more preferably 65% by mass or less. The lower limit is preferably 50% by mass or more and more preferably 55% by mass or more.

<<Infrared Absorber>>

The composition according to the embodiment of the present invention can contain an infrared absorber. In an infrared transmitting filter, the infrared absorber has a function of limiting transmitted light (near infrared rays) to a longer wavelength side.

In the present invention, as the infrared absorber, a compound having a maximum absorption wavelength in a wavelength range of an infrared range (preferably, a wavelength range of more than 700 nm and 1300 nm or less) can be preferably used. The infrared absorber may be a pigment or a dye.

Examples of the infrared absorber include a pyrrolopyrrole compound, a cyanine compound, a phthalocyanine compound, a diiminium compound, a transition metal oxide, a squarylium compound, a naphthalocyanine compound, a quaterylene compound, a dithiol metal complex compound, a croconium compound, and an oxonol compound. Examples of the pyrrolopyrrole compound include compounds described in paragraphs 0016 to 0058 of JP2009-263614A, and compounds described in paragraphs 0037 to 0052 of JP2011-068731A, the contents of which are incorporated in this specification. Examples of the squarylium compound include compounds described in paragraphs 0044 to 0049 of JP2011-208101A, the content of which is incorporated in this specification. Examples of the cyanine compound include compounds described in paragraphs 0044 to 0045 of JP2009-108267A, and compounds described in paragraphs 0026 to 0030 of JP2002-194040A, the contents of which are incorporated in this specification. Examples of the diiminium compound include compounds described in JP2008-528706A, the content of which is incorporated in this specification. Examples of the phthalocyanine compound include compounds described in paragraph 0093 of JP2012-077153A, oxytitanium phthalocyanine described in JP2006-343631A, and compounds described in paragraphs 0013 to 0029 of JP2013-195480A, the contents of which are incorporated in this specification. Examples of the naphthalocyanine compound include compounds described in paragraph 0093 of JP2012-077153A, the content of which is incorporated in this specification. Examples of the oxonol compound include compounds described in paragraphs 0039 to 0066 of JP2006-001875A, the content of which is incorporated in this specification. In addition, as the cyanine compound, the phthalocyanine compound, the diiminium compound, the squarylium compound, and the croconium compound, compounds described in paragraphs 0010 to 0081 of JP2010-111750A may be used, and the contents thereof are incorporated in this specification. In addition, regarding the cyanine compound, for example, “Functional Colorants by Makoto Okawara, Masaru Matsuoka, Teijiro Kitao, and Tsuneoka Hirashima, published by Kodansha Scientific Ltd.” can be referred to and the content thereof is incorporated in this specification. Specific examples of the infrared absorber include a compound Q-3, a compound S-6, and a compound O-4, which will be described in examples below.

In the present invention, as the infrared absorber, compounds described in paragraphs 0004 to 0016 of JP1995-164729A (JP-H07-164729A), compounds described in paragraphs 0027 to 0062 of JP2002-146254A, or near infrared ray absorbing particles described in paragraphs 0034 to 0067 of JP2011-164583A which are formed of crystallites of an oxide including Cu and/or P and have a number average aggregated particle diameter of 5 to 200 nm may be used, the contents of which are incorporated in this specification. In addition, for example, FD-25 (manufactured by Yamada Chemical Co., Ltd.) or IRA842 (naphthalocyanine compound, manufactured by Exiton, Inc.) can also be used.

In addition, as the infrared absorber, inorganic fine particles can be used. The inorganic fine particles are preferably metal oxide particles or fine metal particles from the viewpoint of excellent infrared ray shielding properties. Examples of the metal oxide particles include indium tin oxide (ITO) particles, antimony tin oxide (ATO) particles, zinc oxide (ZnO) particles, Al-doped zinc oxide (Al-doped ZnO) particles, fluorine-doped tin dioxide (F-doped SnO₂) particles, and niobium-doped titanium dioxide (Nb-doped TiO₂) particles. Examples of the fine metal particles include silver (Ag) particles, gold (Au) particles, copper (Cu) particles, and nickel (Ni) particles. In addition, as the inorganic fine particles, a tungsten oxide-based compound can be used. The tungsten oxide-based compound is preferably a cesium tungsten oxide. Regarding the details of the tungsten oxide-based compound, paragraph 0080 of JP2016-006476A can be referred to and the content thereof is incorporated in this specification. The shape of the inorganic fine particle is not particularly limited and may have a sheet shape, a wire shape, or a tube shape irrespective of whether or not the shape is spherical or non-spherical.

In a case where the composition according to the embodiment of the present invention contains the infrared absorber, the content of the infrared absorber is preferably 1% to 60% by mass and more preferably 10% to 40% by mass with respect to the total solid content of the composition. In addition, the content of the infrared absorber is preferably 10 to 200 parts by mass, more preferably 20 to 150 parts by mass, and even more preferably 30 to 80 parts by mass with respect to 100 parts by mass of the coloring material which shields visible light. In the composition according to the embodiment of the present invention, one kind of infrared absorber may be used alone or two or more kinds of infrared absorbers may be used in combination. In a case where two or more kinds of infrared absorbers are used in combination, the total amount is preferably in the above range.

<<Curable Compound>>

The composition according to the embodiment of the present invention contains a curable compound. The curable compound may be a compound having a crosslinkable group (hereinafter, also referred to as a crosslinkable compound) or may be a resin not having a crosslinkable group. In addition, the crosslinkable compound may be a monomer or a resin. The term “crosslinkable group” means a group having a portion which reacts due to the action of heat, light or a radical to form a crosslinking bond. Examples of the crosslinkable group include a group having an ethylenically unsaturated bond, an epoxy group, and an alkoxysilyl group, and an epoxy group is preferable. In the present invention, the term “resin” means a polymer or prepolymer.

In the present invention, the curable compound preferably includes at least a crosslinkable compound and more preferably includes at least a compound having an epoxy group. The shrinkage of the compound having an epoxy group due to crosslinking is small. Therefore, by using a compound having an epoxy group as the curable compound, the rectangularity and dimensional stability of the obtained pattern are excellent.

The crosslinkable group value of the crosslinkable compound is preferably 0.1 to 10.0 mmol/g. The upper limit is preferably 9.5 mmol/g or less, more preferably 9.0 mmol/g or less, and even more preferably 8.0 mmol/g or less.

In addition, in a case where the crosslinkable compound is a compound having an epoxy group, the epoxy group value of the crosslinkable compound is preferably 0.1 to 10.0 mmol/g. The upper limit is preferably 9.5 mmol/g or less, more preferably 9.0 mmol/g or less, and even more preferably 8.0 mmol/g or less.

In addition, in the present invention, it is preferable that the curable compound includes a resin (hereinafter, also referred to as a resin A). It is more preferable that the resin A includes at least a resin A1 having a crosslinkable group and a resin A2 having an acid group.

In this case, the sum of the crosslinkable group value and the acid value in the resin is preferably 0.1 to 10.0 mmol/g. The upper limit is preferably 9.0 mmol/g or less, more preferably 8.0 mmol/g or less, and even more preferably 7.0 mmol/g or less. The lower limit is preferably 1.0 mmol/g or more, more preferably 2.0 mmol/g or more, and even more preferably 3.0 mmol/g or more. As long as the sum of the crosslinkable group value and the acid value in resin A is in the above range, the cured film can be prevented from being damaged during a dry etching step or subsequent resist stripping. Therefore, it is possible to form a pattern having a good pattern shape and a good surface state of the etching cross section.

It is preferable that the above-described resin A1 is a resin having an epoxy group. In a case where the resin A1 is a resin having an epoxy group, the epoxy group value of the resin A1 is preferably 0.1 to 9.9 mmol/g. The upper limit is preferably 8.0 mmol/g or less, more preferably 6.0 mmol/g or less, and even more preferably 4.0 mmol/g or less.

The above-described resin A2 may be either a resin not having a crosslinkable group or a resin having a crosslinkable group, but the resin is preferably a resin having a crosslinkable group. As the crosslinkable group of the resin A2, the crosslinkable groups described above may be adopted and a group having an ethylenically unsaturated bond and an epoxy group are preferable. The acid value of the above-described resin A2 is preferably 0.1 to 9.9 mmol/g and more preferably 0.1 to 3.0 mmol/g. The upper limit is preferably 2.8 mmol/g or less, more preferably 2.5 mmol/g or less, and even more preferably 2.0 mmol/g or less. In a case where the above-described resin A2 is a resin having a crosslinkable group, the crosslinkable group value of the resin A2 is preferably 0.1 to 9.9 mmol/g and more preferably 0.1 to 3.0 mmol/g. The upper limit is preferably 2.8 mmol/g or less, more preferably 2.5 mmol/g or less, and even more preferably 2.0 mmol/g or less.

In the present invention, the crosslinkable group value is the content of the crosslinkable group per 1 g of the compound. Examples of the crosslinkable group include a group having an ethylenically unsaturated bond, an epoxy group, and an alkoxysilyl group. In addition, the epoxy group value is the content of the epoxy group per 1 g of the compound. In addition, the acid value is the content of the acid group per 1 g of the compound. Examples of the acid group include a carboxyl group, a phosphoric acid group, a sulfo group, and a phenolic hydroxyl group.

In the composition according to the embodiment of the present invention, the content of the curable compound is preferably 1.0% to 60.0% by mass with respect to the total solid content of the composition. The lower limit is preferably 2.0% by mass or more, more preferably 3.0% by mass or more, and even more preferably 5.0% by mass or more. The upper limit is 50.0% by mass or less, more preferably 40.0% by mass or less, and even more preferably 30.0% by mass or less.

In the composition according to the embodiment of the present invention, the content of the crosslinkable compound is preferably 1.0% to 60.0% by mass with respect to the total solid content of the composition. The lower limit is preferably 2.0% by mass or more, more preferably 3.0% by mass or more, and even more preferably 5.0% by mass or more. The upper limit is preferably 55.0% by mass or less, more preferably 50.0% by mass or less, and even more preferably 40.0% by mass or less. In addition, the content of the compound having an epoxy group is preferably 0.1% to 10.0% by mass with respect to the total solid content of the composition. The lower limit is preferably 0.5% by mass or more, more preferably 1.0% by mass or more, and even more preferably 1.5% by mass or more. The upper limit is preferably 10.0% by mass or less, more preferably 7.0% by mass or less, and even more preferably 5.0% by mass or less.

In the composition according to the embodiment of the present invention, the content of the resin is preferably 1.0% to 60.0% by mass with respect to the total solid content of the composition. The lower limit is preferably 2.0% by mass or more, more preferably 5.0% by mass or more, and even more preferably 10.0% by mass or more. The upper limit is preferably 55.0% by mass or less, more preferably 50.0% by mass or less, and even more preferably 40.0% by mass or less. In addition, the content of the resin A1 having a crosslinkable group is preferably 1.0% to 60.0% by mass with respect to the total solid content of the composition. The lower limit is preferably 2.0% by mass or more, more preferably 5.0% by mass or more, and even more preferably 10.0% by mass or more. The upper limit is preferably 55.0% by mass or less, more preferably 50.0% by mass or less, and even more preferably 40.0% by mass or less. In addition, the content of the resin A2 having an acid group is preferably 1.0 to 300.0 parts by mass with respect to 100 parts by mass of the resin A1 having a crosslinkable group. The lower limit is preferably 5.0 parts by mass or more, more preferably 50.0 parts by mass or more, and even more preferably 100.0 parts by mass or more. The upper limit is preferably 300.0 parts by mass or less, more preferably 250.0 parts by mass or less, and even more preferably 150.0 parts by mass or less.

In the composition according to the embodiment of the present invention, the content of the crosslinkable compound in the curable compound is preferably 0.1% to 30.0% by mass. The lower limit is preferably 0.5% by mass or more, more preferably 1.0% by mass or more, and even more preferably 3.0% by mass or more. The upper limit is preferably 25.0% by mass or less, more preferably 20.0% by mass or less, and even more preferably 15.0% by mass or less. In addition, the content of the compound having an epoxy group in the curable compound is preferably 0.1% to 20.0% by mass. The lower limit is preferably 0.5% by mass or more, more preferably 1.0% by mass or more, and even more preferably 3.0% by mass or more. The upper limit is preferably 20.0% by mass or less, more preferably 15.0% by mass or less, and even more preferably 10.0% by mass or less.

In the composition according to the embodiment of the present invention, the content of the curable compound is preferably 10 to 100 parts by mass with respect to 100 parts by mass of the pigment. The upper limit is preferably 80 parts by mass or less and more preferably 75 parts by mass or less. The lower limit is preferably 15 parts by mass or more, more preferably 20 parts by mass or more, and even more preferably 25 parts by mass or more. In addition, the content of the resin is preferably 10 to 100 parts by mass with respect to 100 parts by mass of the pigment. The upper limit is preferably 80 parts by mass or less and more preferably 75 parts by mass or less. The lower limit is preferably 15 parts by mass or more, more preferably 20 parts by mass or more, and even more preferably 25 parts by mass or more. In the composition according to the embodiment of the present invention, as the coloring material which shields visible light, various pigments may be used in combination in some cases. In a case where a pattern is formed using a composition including various kinds of pigments by a dry etching method, the pigments may float on the etching cross section to cause roughness or the like on the pattern cross section in some cases. However, within the above range, the surface state of the etching cross section can be further improved.

Hereinafter, the curable compound will be described in detail.

<<<Crosslinkable Compound>>>

In the composition according to the embodiment of the present invention, as a curable compound, a crosslinkable compound can be used. As the curable compound, a compound including at least a crosslinkable compound is preferably used. As the crosslinkable compound, a known compound which is crosslinkable by a radical, an acid, or heat can be used. A compound which is crosslinkable by heat is preferable. Examples of the crosslinkable compound include a compound having a group having an ethylenically unsaturated bond, a compound having an epoxy group, and a compound having an alkoxysilyl group. Examples of the compound having a group having an ethylenically unsaturated bond include a vinyl group, a (meth)allyl group, and a (meth)acryloyl group. Examples of the alkoxysilyl group include a monoalkoxysilyl group, a dialkoxysilyl group, a trialkoxysilyl group, and a tetraalkoxysilyl group. The crosslinkable compound may be a monomer or a resin. As the crosslinkable compound, a compound having an epoxy group is preferable.

The molecular weight of the monomer type crosslinkable compound is preferably less than 2000, more preferably 100 or more and less than 2000, and even more preferably 200 or more and less than 2000. For example, the upper limit is preferably 1500 or less. The weight-average molecular weight (Mw) of the resin type crosslinkable compound is preferably 2,000 to 2,000,000. The upper limit is preferably 1,000,000 or less and more preferably 500,000 or less. The lower limit is preferably 3,000 or more and more preferably 5,000 or more.

Examples of the resin type crosslinkable compound include an epoxy resin and a resin which includes a repeating unit having a crosslinkable group, which will be described later. Examples of the repeating unit having a crosslinkable group include the following (A2-1) to (A2-4).

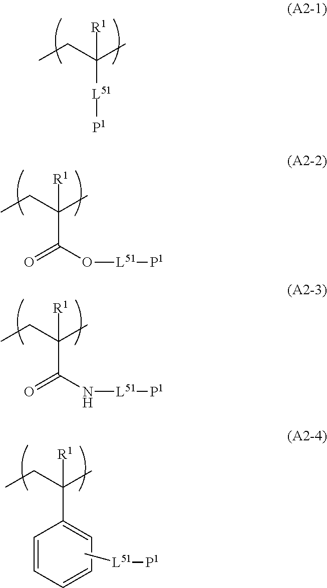

R¹ represents a hydrogen atom or an alkyl group. The number of carbon atoms in the alkyl group is preferably 1 to 5, more preferably 1 to 3, and particularly preferably 1. R¹ preferably represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably represents a hydrogen atom), and a group including a combination thereof. A group including a combination of at least one of an alkylene group, an arylene group, or an alkylene group, and —O— is preferable. The number of carbon atoms in the alkylene group is preferably 1 to 30, more preferably 1 to 15, and even more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and even more preferably 6 to 10.

P¹ represents a crosslinkable group. Examples of the crosslinkable group include a group having an ethylenically unsaturated bond, an epoxy group, and an alkoxysilyl group.

(Compound Having Group Having Ethylenically Unsaturated Bond)

As the compound having a group having an ethylenically unsaturated bond, a (meth)acrylate compound having 3 to 15 functional groups is preferable and a (meth)acrylate compound having 3 to 6 functional groups is more preferable. Regarding examples of the compound having a group having an ethylenically unsaturated bond, the description of paragraphs 0033 and 0034 of JP2013-253224A can be referred to and the content thereof is incorporated in this specification. Specific examples thereof include dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.).

Ethyleneoxy-modified pentaerythritol tetraacrylate (as a commercially available product, NK ESTER ATM-35E; manufactured by Shin-Nakamura Chemical Co., Ltd.), dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.), or a structure in which the (meth)acryloyl group is bonded through an ethylene glycol or a propylene glycol residue is preferable. In addition, oligomers of the above examples can be used. In addition, regarding the compound having an ethylenically unsaturated bond, the description of a polymerizable compound in paragraphs 0034 to 0038 of JP2013-253224A can be referred to and the content thereof is incorporated in this specification. Examples of the compound having an ethylenically unsaturated bond include a polymerizable monomer in paragraph 0477 of JP2012-208494A (corresponding to paragraph 0585 of US2012/0235099A), the content of which is incorporated in this specification. Further, diglycerin ethylene oxide (EO)-modified (meth)acrylate (as a commercially available product, M-460 manufactured by Toagosei Co., Ltd.) is preferable. Pentaerythritol tetraacrylate (A-TMMT manufactured by Shin-Nakamura Chemical Co., Ltd.) or 1,6-hexanediol diacrylate (KAYARAD HDDA manufactured by Nippon Kayaku Co., Ltd.) is also preferable. Oligomers of the above examples can be used. For examples, RP-1040 (manufactured by Nippon Kayaku Co., Ltd.) is used.

The compound including a group having an ethylenically unsaturated bond may further have an acid group such as a carboxyl group, a sulfo group, or a phosphoric acid group. Examples of commercially available products include ARONIX series (for example, M-305, M-510, and M-520) manufactured by Toagosei Co., Ltd.

A compound having a caprolactone structure is also preferable as the compound including a group having an ethylenically unsaturated bond. Regarding the compound having a caprolactone structure, the description of paragraphs 0042 to 0045 of JP2013-253224A can be referred to and the content thereof is incorporation in this specification. Examples of commercially available products include SR-494 (manufactured by Sartomer) which is a tetrafunctional acrylate having four ethyleneoxy chains, DPCA-60 (manufactured by Nippon Kayaku Co., Ltd.) which is a hexafunctional acrylate having six pentyleneoxy chains, and TPA-330 (manufactured by Nippon Kayaku Co., Ltd.) which is a trifunctional acrylate having three isobutyleneoxy chains.

(Compound Having Epoxy Group)

Examples of the compound having an epoxy group include a monofunctional or polyfunctional glycidyl ether compound and a polyfunctional aliphatic glycidyl ether compound. As the compound having an epoxy group, a compound having an alicyclic epoxy group can be used.

As the compound having an epoxy group, a compound having one or more epoxy groups in one molecule may be used. The number of epoxy groups in one molecule is preferably 1 to 100. The upper limit can be set to, for example, 10 or less or 5 or less. The lower limit is preferably 2 or more.

The compound having an epoxy group may be a low molecular weight compound (for example, molecule weight: lower than 1000) or a high molecular weight compound (macromolecule; for example, molecular weight: 1000 or higher, and in a case of a polymer, weight-average molecular weight: 1000 or higher). The weight-average molecular weight of the compound having an epoxy group is preferably 2000 to 100000. The upper limit of the weight-average molecular weight is preferably 10000 or less, more preferably 5000 or less, and even more preferably 3000 or less. The epoxy compound is preferably an aliphatic epoxy resin from the viewpoint of solvent resistance.

The compound having an epoxy group is preferably a compound having an aromatic ring and/or an aliphatic ring and more preferably a compound having an aliphatic ring. In addition, the epoxy group is preferably bonded to the aromatic ring and/or the aliphatic ring through a single bond or a linking group. Examples of the linking group include an alkylene group, an arylene group, —O—, —NR′— (R′ represents a hydrogen atom, an alkyl group, or an aryl group and preferably represents a hydrogen atom), —SO₂—, —CO—, —O—, —S—, and a group including a combination thereof. As the compound having an epoxy group, a compound in which the epoxy group is directly bonded (single bond) to the aliphatic ring is more preferable.

Examples of commercially available products of the compound having an epoxy group include EHPE3150 (manufactured by Daicel Corporation), and EPICLON N-695 (manufactured by DIC Corporation). In addition, as the compound having an epoxy group, compounds described in paragraphs 0034 to 0036 of JP2013-011869A, paragraphs 0147 to 0156 of JP2014-043556A, and paragraphs 0085 to 0092 of JP2014-089408A can also be used. The contents thereof are incorporated in this specification.

(Compound Having Alkoxysilyl Group)

In the compound having an alkoxysilyl group, the number of carbon atoms of the alkoxy group in the alkoxysilyl group is preferably 1 to 5, more preferably 1 to 3, and particularly preferably 1 or 2. The number of alkoxysilyl groups in one molecule is preferably 2 or more. Specific examples of the compound having an alkoxysilyl group include tetraethoxysilane. In addition, compounds described in paragraph 0044 of JP2014-203044A and compounds described in paragraphs 0044 to 0047 of JP2015-125710A are included and the contents thereof are incorporated in this specification.

<<<Resin>>>

In the composition according to the embodiment of the present invention, as the curable compound, a resin can be used. As the curable compound, a compound including at least a resin is preferably used. The resin can be used as a dispersant. The resin used to disperse the pigment or the like is also called a dispersant. However, the above uses of the resin are merely exemplary, and the resin can be used for purposes other than the uses. The resin having a crosslinkable group also corresponds to a crosslinkable compound.

The weight-average molecular weight (Mw) of the resin is preferably 2,000 to 2,000,000. The upper limit is preferably 1,000,000 or less and more preferably 500,000 or less. The lower limit is preferably 3,000 or more and more preferably 5,000 or more.

Examples of the resin include a (meth)acrylic resin, an epoxy resin, an ene-thiol resin, a polycarbonate resin, a polyether resin, polyallylate resin, a polysulfone resin, a polyether sulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind of resin may be used or two or more kinds of resins may be used as a mixture. Examples of the epoxy resin include epoxy resins described the above-described section of the crosslinkable compound. In addition, MARPROOF G-0150M, G-0105SA, G-0130SP, G-0250SP, G-1005S, G-1005SA, G-1010S, G-2050M, G-01100, and G-01758 (epoxy group-containing polymer, manufactured by NOF Corporation) can be used.

The resin used in the present invention may have an acid group. Examples of the acid group include a carboxyl group, a phosphoric acid group, a sulfo group, and a phenolic hydroxyl group. Among these acid groups, one kind may be used or two or more kinds may be used. The resin having an acid group can be preferably used as a dispersant.

As the resin having an acid group, a polymer having a carboxyl group at a side chain thereof is preferable. Specific examples thereof include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac type resin, an acidic cellulose derivative having a carboxyl group at a side chain thereof, and a resin obtained by adding an acid anhydride to a polymer having a hydroxyl group. In particular, a copolymer of (meth)acrylic acid and another monomer which is copolymerizable with the (meth)acrylic acid is suitable as the alkali-soluble resin. Examples of another monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. As another monomer, N-position-substituted maleimide monomers described in JP1998-300922A (JP-H10-300922A) such as N-phenylmaleimide or N-cyclohexylmaleimide can be used. Among these monomers which are copolymerizable with the (meth)acrylic acid, one kind of monomer may be used or two or more kinds of monomers may be used. Specific examples of the resin having an acid group include resins having the following structures.

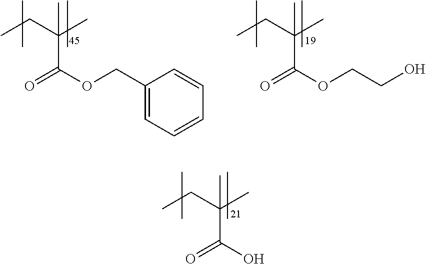

The resin having an acid group may further contain a repeating unit having a crosslinkable group. Examples of the repeating unit having a crosslinkable group include repeating units represented by the above Formulae (A2-1) to (A2-4). In a case where the resin having an acid group contains the repeating unit having a crosslinkable group, the content of the repeating unit having a crosslinkable group is preferably 10% to 90% by mole, more preferably 20% to 90% by mole, and even more preferably 20% to 85% by mole with respect to all the repeating units. In addition, the content of the repeating unit having an acid group is preferably 1% to 50% by mole, more preferably 5% to 40% by mole, and even more preferably 5% to 30% by mole with respect to all the repeating units. Specific examples thereof include the following resins.

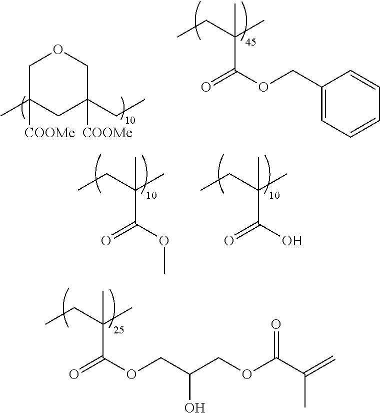

As the resin having an acid group, a copolymer including benzyl (meth)acrylate and (meth)acrylic acid, a copolymer including benzyl (meth)acrylate, (meth)acylic acid, and 2-hydroxyethyl (meth)acrylate, or a multi-component copolymer including benzyl (meth)acrylate, (meth)acrylic acid, and another monomer can be preferably used. In addition, copolymers described in JP1995-140654A (JP-H7-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid, a copolymer including 2-hydroxy-3-phenoxypropyl acrylate, a polymethyl methacrylate macromonomer, benzyl methacrylate, and methacrylic acid, a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

As the resin having an acid group, a polymer obtained by copolymerization of monomer components including a compound represented by the following Formula (ED1) and/or a compound represented by the following Formula (ED2) (hereinafter, these compounds are also be referred to as “ether dimer”) is also preferable.

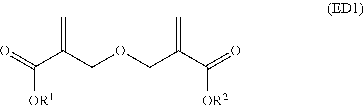

In Formula (ED1), R¹ and R² each independently represent a hydrogen atom or a hydrocarbon group having 1 to 25 carbon atoms which may have a substituent.

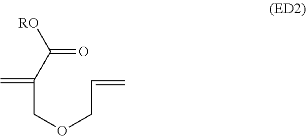

In Formula (ED2), R represents a hydrogen atom or an organic group having 1 to 30 carbon atoms. Regarding specific examples of Formula (ED2), the description of JP2010-168539A can be referred to.

Regarding specific examples of the ether dimer, for example, paragraph 0317 of JP2013-029760A can be referred to and the content thereof is incorporated in this specification. One kind of ether dimer may be used or two or more kinds of ether dimers may be used.

The resin having an acid group may include a repeating unit derived from a compound represented by the following Formula (X).

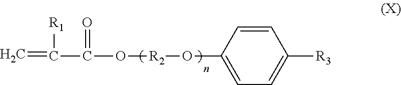

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

Regarding the resin having an acid group, the descriptions of paragraphs 0558 to 0571 of JP2012-208494A (corresponding to paragraphs 0685 to 0700 of US2012/0235099A), the content of which is incorporated herein by reference, and paragraphs 0076 to 0099 of JP2012-198408A can be referred to and the contents thereof are incorporated in this specification. In addition, a commercially available product can be used as the resin having an acid group. For example, ACRYLBASE FF-426 (manufactured by Fujikura Kasei Co., Ltd.) may be used.

The acid value of the resin having an acid group is preferably 0.5 to 4.0 mmol/g. The lower limit is preferably 0.8 mmol/g or more and more preferably 1.0 mmol/g or more. The upper limit is preferably 3.0 mmol/g or less and more preferably 2.5 mmol/g or less.

In the present invention, as the resin, a graft copolymer including a repeating unit represented by any one of the following Formulae (111) to (114) is preferably used. The resin can be preferably used as a dispersant.

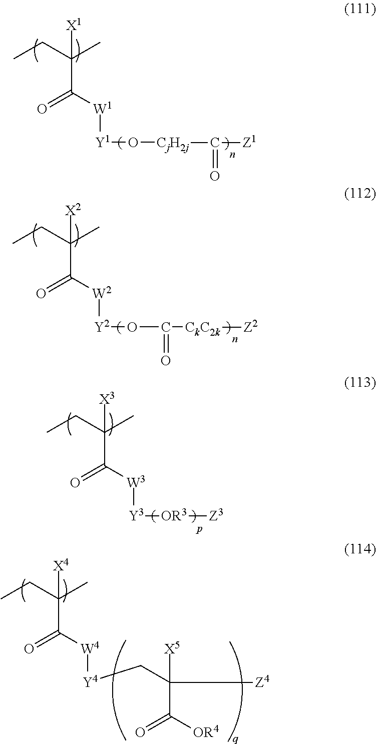

In Formulae (111) to (114), W¹, W², W³, and W⁴ each independently represent an oxygen atom or NH, X¹, X², X³, X⁴, and X⁵ each independently represent a hydrogen atom or a monovalent group, Y¹, Y², Y³, and Y⁴ each independently represent a divalent linking group, Z¹, Z², Z³, and Z⁴ each independently represent a monovalent group, R³ represents an alkylene group, R⁴ represents a hydrogen atom or a monovalent group, n, m, p, and q each independently represent an integer of 1 to 500, j and k each independently represent an integer of 2 to 8, when p is an integer of 2 to 500 in Formula (113), a plurality of R³'s may be the same as or different from each other, and when q is an integer of 2 to 500 in Formula (114), a plurality of X⁵'s and a plurality of R⁴'s may be the same as or different from each other.

Regarding the details of the graft copolymer, the description of paragraphs 0025 to 0094 of JP2012-255128A can be referred to and the content thereof is incorporated in this specification. Specific examples of the graft copolymer include the following resins. In addition, resins described in paragraphs 0072 to 0094 of JP2012-255128A may be used and the content thereof is incorporated in this specification.

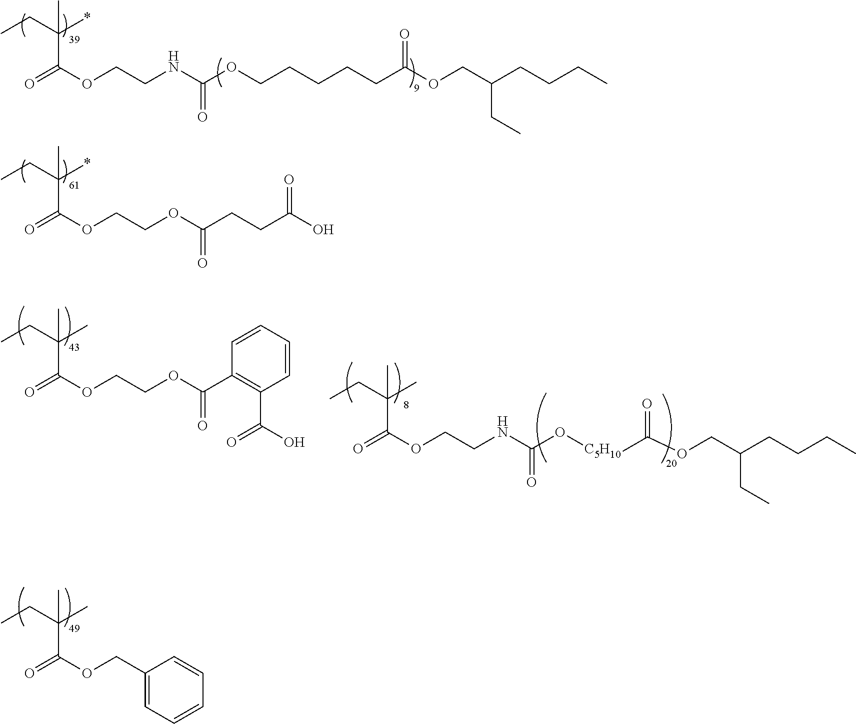

In addition, in the present invention, as the resin, an oligoimine-based resin having a nitrogen atom in at least one of a main chain or a side chain is preferably used. As the oligoimine-based resin, a resin, which includes a repeating unit having a partial structure X with a functional group having a pKa of 14 or lower and a side chain including a side chain Y having 40 to 10,000 atoms, and has a basic nitrogen atom in at least one of a main chain or a side chain, is preferable. The basic nitrogen atom is not particularly limited as long as it is a nitrogen atom exhibiting basicity. Examples of the oligoimine-based resin include a resin including a repeating unit represented by the following Formula (I-1), a repeating unit represented by the following Formula (1-2), and/or a repeating unit represented by the following Formula (I-2a). The resin can be preferably used as a dispersant.

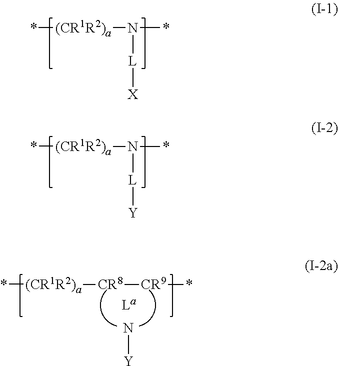

R¹ and R² each independently represent a hydrogen atom, a halogen atom, or an alkyl group (having preferably 1 to 6 carbon atoms). a's each independently represent an integer of 1 to 5. * represents a linking portion between repeating units.

R⁸ and R⁹ represent the same group as that of R¹.

L represents a single bond, an alkylene group (having preferably 1 to 6 carbon atoms), an alkenylene group (having preferably 2 to 6 carbon atoms), an arylene group (having preferably 6 to 24 carbon atoms), a heteroarylene group (having preferably 1 to 6 carbon atoms), an imino group (having preferably 0 to 6 carbon atoms), an ether group, a thioether group, a carbonyl group, or a linking group of a combination of the above-described groups. Among these, a single bond or —CR⁵R⁶—NR⁷— (an imino group is present at the X or Y site) is preferable. Here, R⁵ and R⁶ each independently represent a hydrogen atom, a halogen atom, or an alkyl group (having preferably 1 to 6 carbon atoms). R⁷ represents a hydrogen atom or an alkyl group having 1 to 6 carbon atoms.

L^{a} is a structural unit which forms a ring structure with CR⁸CR⁹ and a nitrogen atom (N) and is preferably a structural unit which forms a nonaromatic heterocycle having 3 to 7 carbon atoms with carbon atoms of CR⁸CR⁹. L^{a} is more preferably a structural unit which forms a nonaromatic 5- to 7-membered heterocycle with carbon atoms of CR⁸CR⁹ and a nitrogen atom (N), still more preferably a structural unit which forms a nonaromatic 5-membered heterocycle with CR⁸CR⁹ and N, and particularly preferably a structural unit which forms pyrrolidine with CR⁸CR⁹ and N. This structural unit may have a substituent such as an alkyl group.

X represents a group having a functional group having a pKa of 14 or lower.

Y represents a side chain having 40 to 10,000 atoms.

The oligoimine-based resin may further include one or more copolymerization components selected from the group consisting of the repeating units represented by Formulae (1-3), (I-4), and (1-5).

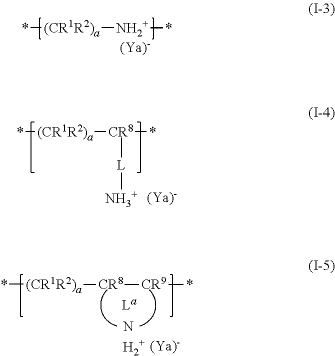

R¹, R², R⁸, R⁹, L, L^{a}, a, and * have the same definitions as R¹, R², R⁸, R⁹, L, L^{a}, a, and * in Formulae (I-1), (1-2), and (I-2a).

Ya represents a side chain having 40 to 10,000 atoms which has an anionic group. The repeating unit represented by Formula (1-3) can be formed by adding an oligomer or a polymer having a group, which reacts with amine to form a salt, to a resin having a primary or secondary amino group at a main chain such that the components react with each other.

Regarding the oligoimine-based resin, the description of paragraphs 0102 to 0166 of JP2012-255128A can be referred to and the content thereof is incorporated in this specification. Specific examples of the oligoimine-based resin are as follows. In addition, resins described in paragraphs 0168 to 0174 of JP2012-255128A can be used.

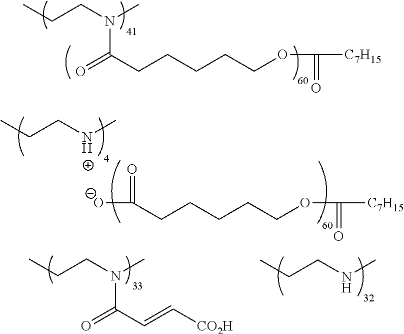

As the resin used as a dispersant, a commercially available product is available and specific examples thereof include Disperbyk-111 (manufactured by BYK Chemie GmbH). In addition, pigment dispersants described in paragraphs 0041 to 0130 of JP2014-130338A can be used and the content thereof is incorporated in this specification.

<<Pigment Derivative>>

The composition according to the embodiment of the present invention can contain a pigment derivative. Examples of the pigment derivative include a compound having a structure in which a part of a pigment is substituted with an acid group, a basic group, or a phthalimidomethyl group. It is preferable that the pigment derivative has an acid group or a basic group from the viewpoints of dispersibility and dispersion stability pigment. Examples of an organic pigment for constituting the pigment derivative include a pyrrolopyrrole pigment, a diketopyrrolopyrrole pigment, an azo pigment, a phthalocyanine pigment, an anthraquinone pigment, a quinacridone pigment, a dioxazine pigment, a perinone pigment, a perylene pigment, a thioindigo pigment, an isoindoline pigment, an isoindolinone pigment, a quinophthalone pigment, a threne pigment, and a metal complex pigment. In addition, as the acid group included in the pigment derivative, a carboxyl group or a sulfo group is preferable and a sulfo group is more preferable. As the basic group included in the pigment derivative, an amino group is preferable and a tertiary amino group is more preferable.

The content of the pigment derivative is preferably 1% to 50% by mass and more preferably 3% to 30% by mass with respect to the total mass of the pigment. Among these pigment derivatives, one kind may be used alone, or two or more kinds may be used in combination.

<<<Polyfunctional Thiol Compound>>>

The composition according to the embodiment of the present invention may include a polyfunctional thiol compound having two or more mercapto groups in one molecule in order to promote a reaction of the curable compound. The polyfunctional thiol compound is preferably a secondary alkanethiol and particularly preferably a compound having a structure represented by the following Formula (T1).

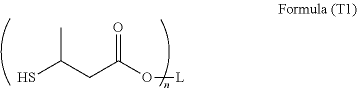

In Formula (T1), n represents an integer of 2 to 4, and L represents a divalent to tetravalent linking group.

The content of the polyfunctional thiol compound is preferably 0.3% to 8.9% by mass and more preferably 0.8% to 6.4% by mass with respect to the total solid content of the composition. In addition, the polyfunctional thiol compound may be added in order to improve stability, odor, resolution, developability, adhesiveness, and the like.

<<Photopolymerization Initiator>>

The composition according to the embodiment of the present invention preferably contains a photopolymerization initiator in a case where a compound having an ethylenically unsaturated bond is used as the curable compound. The photopolymerization initiator is not particularly limited as long as it has the ability to initiate the polymerization of the compound having an ethylenically unsaturated bond, and can be selected from known photopolymerization initiators. For example, a compound having photosensitivity to light in a range from the ultraviolet range to the visible range is preferable. The photopolymerization initiator is preferably a photo radical polymerization initiator. Examples of the photopolymerization initiator include a halogenated hydrocarbon derivative (for example, a compound having a triazine skeleton or an oxadiazole skeleton), an acylphosphine compound such as acylphosphine oxide, an oxime compound such as hexaarylbiimidazole or an oxime derivative, an organic peroxide, a thio compound, a ketone compound, an aromatic onium salt, keto oxime ether, an aminoacetophenone compound, and hydroxyacetophenone. From the viewpoint of exposure sensitivity, the photopolymerization initiator is preferably a compound selected from the group consisting of a trihalomethyltriazine compound, a benzyldimethylketanol compound, an α-hydroxy ketone compound, an α-amino ketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, and a halomethyl oxadiazole compound, a 3-aryl-substituted coumarin compound, and an oxime compound is more preferable. Regarding the photopolymerization initiator, the description of paragraphs 0065 to 0111 of JP2014-130173A can be referred to and the content thereof is incorporated in this specification.

The content of the photopolymerization initiator is preferably 0.1% to 50% by mass, more preferably 0.5% to 30% by mass, and even more preferably 1% to 20% by mass with respect to the total solid content of the composition. As long as the content of the photopolymerization initiator is in the above range, better sensitivity and pattern formability can be obtained. The composition according to the embodiment of the present invention may include one kind of photopolymerization initiator or two or more kinds of photopolymerization initiators. In a case where the composition includes two or more kinds of photopolymerization initiators, the total amount is preferably in the above range.

<<Solvent>>

The composition according to the embodiment of the present invention can contain a solvent. As the solvent, an organic solvent may be used. The solvent is not particularly limited as long as it satisfies the solubility of each component and the application properties of the composition, and is preferably selected in consideration of and the application properties of the composition and safety.

Examples of the organic solvent include esters, ethers, ketones, and aromatic hydrocarbons. Specific examples thereof include methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butyl carbitol acetate, propylene glycol methyl ether, and propylene glycol monomethyl ether acetate. Regarding the details of the organic solvent, the description of paragraph 0223 of WO2015/166779A, and the content thereof is incorporated in this specification.

However, it is preferable to reduce aromatic hydrocarbons (benzene, toluene, xylene, ethylbenzene, and the like) as the solvent for environmental reasons or the like (for example, the content thereof can be set to 50 parts per million (ppm) by mass or less, 10 ppm by mass or less, or 1 ppm by mass or less with respect to the total amount of the organic solvent) in some cases.

One kind of organic solvent may be used alone or two or more kinds of organic solvents may be used in combination. In a case where two or more kinds of organic solvents are used in combination, a mixed solution including two or more kinds of organic solvents selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethylcarbitol acetate, butyl carbitol acetate, propylene glycol methyl ether, and propylene glycol methyl ether acetate is preferable.

In the present invention, a solvent having a low metal content is preferably used and for example, the metal content of the solvent is preferably 10 parts per billion (ppb) by mass or less. If necessary, a solvent having a metal content at the parts per trillion (ppt) level may be used, and such a high purity solvent is available from, for example, Toyo Gosei Co., Ltd. (The Chemical Daily, Nov. 13, 2015).

Examples of a method of removing impurities such as metals from a solvent include distillation (molecular distillation, thin film distillation, or the like), and filtering using a filter. The filter pore size in filtering using a filter is preferably 10 nm or less, more preferably 5 nm or less, and even more preferably 3 nm or less. A filter made of polytetrafluoroethylene, polyethylene, or nylon is preferable as the filter.

The solvent may contain isomers (compounds having the same number of atoms and different structures). Also, the organic solvent may include only one kind of isomer or plural kinds of isomers.

In the present invention, it is preferable that the content of peroxide in the organic solvent is 0.8 mmol/L or less and it is more preferable that the organic solvent does not substantially contain a peroxide.

The content of the solvent is preferably 10% to 90% by mass, more preferably 20% to 80% by mass, and 25% to 75% by mass with respect to the total amount of the composition.

<<Polymerization Inhibitor>>

The composition according to the embodiment of the present invention may contain a polymerization inhibitor. Examples of the polymerization inhibitor include hydroquinone, paramethoxyphenol, di-tert-butyl-paracresol, pyrogallol, tert-butylcatechol, benzoquinone, 4,4′-thiobis(3-methyl-6-tert-butylphenol), 2,2′-methylenebis(4-methyl-6-tert-butylphenol), and N-nitrosophenylhydroxylamine cerium (I) salt. Among these, paramethoxyphenol is preferable. The content of the polymerization inhibitor is preferably 0.01% to 5% by mass with respect to the total solid content of the composition.

<<<Surfactant>>>

The composition according to the embodiment of the present invention may contain various surfactants from the viewpoint of further improving application properties. As the surfactant, various surfactants such as a fluorine-based surfactant, a nonionic surfactant, a cationic surfactant, an anionic surfactant, or a silicone-based surfactant can be used. Regarding the surfactant, paragraphs 0238 to 0245 of WO2015/166779A and the content thereof is incorporated in this specification.

By the composition according to the embodiment of the present invention containing a fluorine-based surfactant, the liquid characteristics (for example, fluidity) in a case where a coating solution is prepared are further improved, and the uniformity in coating thickness and liquid saving properties can be further improved. In a case where a film is formed using a coating solution prepared using the composition containing a fluorine-based surfactant, the interfacial tension between a coated surface and the coating solution decreases, the wettability on the coated surface is improved, and the application properties on the coated surface are improved. Therefore, a film having a uniform thickness with reduced unevenness in thickness can be formed more suitably.

The fluorine content in the fluorine-based surfactant is preferably 3% to 40% by mass, more preferably 5% to 30% by mass, and particularly preferably 7% to 25% by mass. The fluorine-based surfactant in which the fluorine content is in the above range is effective from the viewpoint of the uniformity in the thickness of the coating film and liquid saving properties, and the solubility thereof in the composition is also good.

Specific examples of the fluorine-based surfactant include surfactants described in paragraphs 0060 to 0064 of JP2014-041318A (corresponding to paragraphs 0060 to 0064 of WO2014/017669A) and surfactants described in paragraphs 0117 to 0132 of JP2011-132503A, and the contents thereof are incorporated in this specification. Examples of commercially available products of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, and MEGAFACE F780 (all manufactured by DIC Corporation), FLUORAD FC430, FLUORAD FC431, and FLUORAD FC171 (all manufactured by Sumitomo 3M Limited), SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all manufactured by Asahi Glass Co., Ltd.), and PolyFox PF636, PF656, PF6320, PF6520, and PF7002 (all manufactured by OMNOVA Solutions Inc.).

In addition, as the fluorine-based surfactant, it is also possible to suitably use an acrylic compound having a molecular structure having a functional group containing a fluorine atom in which the fluorine atom is volatilized due to a part of the functional group containing a fluorine atom being broken in a case where heat is applied. Examples of such a fluorine-based surfactant include MEGAFACE DS series manufactured by DIC Corporation (The Chemical Daily, Feb. 22, 2016) (Nikkei Business Daily, Feb. 23, 2016), for example, MEGAFACE DS-21, and these surfactants may be used.

A block polymer can also be used as the fluorine-based surfactant. Examples thereof include compounds described in JP2011-089090A. As the fluorine-based surfactant, a fluorine-containing polymer compound containing a repeating unit derived from a (meth)acrylate compound having a fluorine atom and a repeating unit derived from a (meth)acrylate compound having two or more (preferably five or more) alkyleneoxy groups (preferably ethyleneoxy groups or propyleneoxy groups) can also be preferably used. The following compounds are also exemplified as the fluorine-based surfactant used in the present invention.

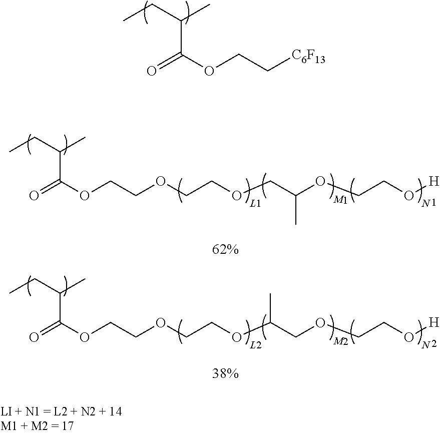

The weight-average molecular weight of the above compound is preferably 3,000 to 50,000, for example, 14,000. In the above compounds, % indicating the proportion of the repeating unit is % by mole.

As the fluorine-based surfactant, a fluorine-containing polymer having an ethylenically unsaturated group at a side chain can also be used. Specific examples include compounds described in paragraphs 0050 of 0090 and paragraphs 0289 to 0295 of JP2010-164965A, for example, MEGAFACE RS-101, RS-102, RS-718K, and RS-72-K manufactured by DIC Corporation. As the fluorine-based surfactant, compounds described in paragraphs 0015 to 0158 of JP2015-117327A can be used.

Examples of the nonionic surfactant include glycerol, trimethylolpropane, trimethylolethane, an ethoxylate and a propoxylate thereof (for example, glycerol propoxylate or glycerin ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid esters, PLURONIC L10, L31, L61, L62, 10R5, 17R2, and 25R2 and TETRONIC 304, 701, 704, 901, 904, and 150R1 (manufactured by BASF SE), SOLSPERSE 20000 (manufactured by Lubrication Technology Inc.), NCW-101, NCW-1001, and NCW-1002 (manufactured by Wako Pure Chemical Industries, Ltd.), PIONIN D-6112, D-6112-W, and D-6315 (manufactured by Takemoto Oil&Fat Co., Ltd.), and OLFINE E1010, SURFYNOL 104, 400, and 440 (manufactured by Nissin Chemical Co., Ltd.).

Only one kind of surfactant may be used or two or more kinds of surfactants may be used in combination.

The content of the surfactant is preferably 0.001% to 2.0% by mass and more preferably 0.005% to 1.0% by mass with respect to the total solid content of the composition.

<<Other Components>>

The composition according to the embodiment of the present invention can contain a thermal polymerization initiator; a thermal polymerization component, an ultraviolet absorber, an antioxidant, a plasticizer, a developability improving agent such as a low molecular weight organic carboxylic acid, and other various additives such as a filler, or an aggregation inhibitor. In addition, as the ultraviolet absorber, an ultraviolet absorber such as an aminodiene compound, a salicylate compound, a benzophenone compound, a benzotriazole compound, an acrylonitrile compound, or a triazine compound can be used, and specific examples thereof include compounds described in JP2013-068814A. As the benzotriazole compound, MYUA series (manufactured by Miyoshi Oil&Fat Co., Ltd., (The Chemical Daily, Feb. 1, 2016) may be used. Further, as the antioxidant, for example, a phenol compound, a phosphorus-based compound (for example, compounds described in paragraph 0042 of JP2011-090147A), a thioether compound, and the like can be used. Examples of commercially available products thereof include ADEKA STAB series (AO-20, AO-30, AO-40, AO-50, AO-50F, AO-60, AO-60G, AO-80, AO-330, and the like), all manufactured by ADEKA.

Depending on materials used and the like, the composition may include a metal element. From the viewpoint of, for example, suppressing the generation of defects, the content of a Group 2 element (for example, calcium or magnesium) in the composition is preferably 50 ppm by mass or less and more preferably 0.01 to 10 ppm by mass. In addition, the total amount of inorganic metal salts in the composition is preferably 100 ppm by mass or less and more preferably 0.5 to 50 ppm by mass.

<Method of Preparing Composition>

The composition according to the embodiment of the present invention can be prepared by mixing the above components with each other.

During the preparation of the composition, the respective components may be mixed with each other collectively or may be mixed with each other sequentially after dissolved and dispersed in a solvent. In addition, during mixing, the order of addition or working conditions are not particularly limited. For example, all the components may be dissolved or dispersed in a solvent at the same time to prepare the composition. If necessary, two or more solutions or dispersion liquids may be prepared in advance using the respective components, and the solutions or dispersion liquids may be mixed with each other during use (during application) to prepare the composition.

Further, the composition according to the embodiment of the present invention includes particles of a pigment or the like, a process of dispersing the particles is preferably provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a project mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that rough particles are removed by filtering, centrifugal separation, and the like. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph 0022 of JP2015-157893A can be suitably used. In addition, in the process of dispersing the particles, particles may be refined in a salt milling step. Regarding a material, a device, process conditions, and the like used in the salt milling step, for example, the description of JP2015-194521A and JP2012-046629A can be referred to.

During the preparation of the composition, it is preferable that the composition is filtered through a filter, for example, in order to remove foreign substances or to reduce defects. As the filter used for filtering, any filter which is used in the related art for filtering or the like can be used without any particular limitation. Examples of the filter include filters formed of the following materials including a fluororesin such as polytetrafluoroethylene (PTFE), a polyamide resin such as nylon (for example, nylon-6 or nylon-6,6), and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is suitably about 0.01 to 7.0 μm and is preferably about 0.01 to 3.0 μm and more preferably about 0.05 to 0.5 μm. In the above range, fine foreign substances can be reliably removed. In addition, it is preferable that a fibrous filter material is used. Examples of the fibrous filter material include polypropylene fiber, nylon fiber, and glass fiber. Specifically, a filter cartridge of SBP type series (manufactured by Roki Techno Co., Ltd.; for example, SBP008), TPR type series (for example, TPR002 or TPR005), SHPX type series (for example, SHPX003), or the like can be used.

In a case of using a filter, a combination of different filters (for example, a first filter, a second filter, and the like) may be used. At this time, the filtering using a first filter may be performed once, or twice or more.

In addition, a combination of first filters having different pore sizes in the above range may be used. Here, the pore size of the filter can refer to a nominal value of a manufacturer of the filter. A commercially available filter can be selected from various filters manufactured by Pall Corporation (for example, DFA4201NIEY), Toyo Roshi Kaisha, Ltd., Entegris Japan Co., Ltd. (former Mykrolis Corporation), or Kits Microfilter Corporation.

A second filter may be formed of the same material as that of the first filter.

For example, the filtering using the first filter may be performed only on the dispersion liquid, and the filtering using the second filter may be performed on a mixture of the dispersion liquid and other components.

The total solid content (concentration of solid contents) of the composition according to the embodiment of the present invention is changed according to the application method, but is preferably, for example, 1% to 50% by mass. The lower limit is more preferably 10% by mass or more. The upper limit is more preferably 30% by mass or less.

It is preferable that the composition according to the embodiment of the present invention satisfies spectral characteristics in which, in a case where a film having a film thickness of 1 μm, 2 μm, 3 μm, 4 μm, or 5 μm after drying is formed, the maximum value of the light transmittance in the thickness direction of the film in a wavelength range of 400 to 700 nm is 20% or less and the minimum value of the light transmittance in the thickness direction of the film in a wavelength range of 1100 to 1300 nm is 70% or more. The maximum value in a wavelength range of 400 to 700 nm is more preferably 15% or less and even more preferably 10% or less. The minimum value in a wavelength range of 1100 to 1300 nm is more preferably 75% or more and even more preferably 80% or more.

In addition, it is more preferable that the composition according to the embodiment of the present invention satisfies any of the following spectral characteristics (1) to (3).

(1): An aspect in which, in a case where a film having a film thickness of 1 μm, 2 μm, 3 μm, 4 μm, or 5 μm after drying is formed, the maximum value of the light transmittance in the thickness direction of the film in a wavelength range of 400 to 750 nm is 20% or less (preferably 15% or less and more preferably 10% or less), and the minimum value of the light transmittance in the thickness direction of the film in a wavelength range of 900 to 1300 nm is 70% or more (preferably 75% or more and more preferably 80% or more).

(2): An aspect in which, in a case where a film having a film thickness of 1 μm, 2 μm, 3 μm, 4 μm, or 5 μm after drying is formed, the maximum value of the light transmittance in the thickness direction of the film in a wavelength range of 400 to 830 nm is 20% or less (preferably 15% or less and more preferably 10% or less), and the minimum value of the light transmittance in the thickness direction of the film in a wavelength range of 1000 to 1300 nm is 70% or more (preferably 75% or more and more preferably 80% or more).

(3): An aspect in which, in a case where a film having a film thickness of 1 μm, 2 μm, 3 μm, 4 μm, or 5 μm after drying is formed, the maximum value of the light transmittance in the thickness direction of the film in a wavelength range of 400 to 950 nm is 20% or less (preferably 15% or less and more preferably 10% or less), and the minimum value of the light transmittance in the thickness direction of the film in a wavelength range of 1100 to 1300 nm is 70% or more (preferably 75% or more and more preferably 80% or more).

<Cured Film>

A cured film obtained using the composition according to the embodiment of the present invention can be preferably used as an infrared transmitting filter.

For the cured film, it is preferable that the maximum value of the light transmittance in the thickness direction of the film in a wavelength range of 400 to 700 nm is 20% or less (preferably 15% or less and more preferably 10% or less), and the minimum value of the light transmittance in the thickness direction of the film in a wavelength range of 1100 to 1300 nm is 70% or more (preferably 75% or more and more preferably 80% or more). According to this aspect, it is possible to form a cured film which shields light in a wavelength range of 400 to 700 nm and allows transmission of infrared rays in a state where noise generated from visible light is small.

The cured film in the present invention preferably has any of the following spectral characteristics (1) to (3). The spectral characteristics of the cured film are values obtained by measuring a transmittance in a wavelength range of 300 to 1300 nm using an ultraviolet-visible-near-infrared spectrophotometer (U-4100, manufactured by Hitachi High-Technologies Corporation).

(1): An aspect in which the maximum value of the light transmittance in the thickness direction of the film in a wavelength range of 400 to 750 nm is 20% or less (preferably 15% or less and more preferably 10% or less), and the minimum value of the light transmittance in the thickness direction of the film in a wavelength range of 900 to 1300 nm is 70% or more (preferably 75% or more and more preferably 80% or more). According to this aspect, it is possible to form a film which shields light in a wavelength range of 400 to 700 nm and allows transmission of infrared rays having a wavelength of more than 850 nm in a state where noise generated from visible light is small.

(2): An aspect in which the maximum value of the light transmittance in the thickness direction of the film in a wavelength range of 400 to 830 nm is 20% or less (preferably 15% or less and more preferably 10% or less), and the minimum value of the light transmittance in the thickness direction of the film in a wavelength range of 1000 to 1300 nm is 70% or more (preferably 75% or more and more preferably 80% or more). According to this aspect, it is possible to form a film which shields light in a wavelength range of 400 to 830 nm and allows transmission of infrared rays having a wavelength of more than 950 nm in a state where noise generated from visible light is small.

(3): An aspect in which the maximum value of the light transmittance in the thickness direction of the film in a wavelength range of 400 to 950 nm is 20% or less (preferably 15% or less and more preferably 10% or less), and the minimum value of the light transmittance in the thickness direction of the film in a wavelength range of 1100 to 1300 nm is 70% or more (preferably 75% or more and more preferably 80% or more). According to this aspect, it is possible to form a film which shields light in a wavelength range of 400 to 950 nm and allows transmission of infrared rays having a wavelength of more than 1100 nm in a state where noise generated from visible light is small.

The cured film having the spectral characteristic (1) can be formed using the composition according to the embodiment of the present invention including a coloring material which shields visible light. Further, by incorporating a chromatic colorant in the composition, the spectrum of the above (1) is easily adjusted to be in a preferable range.

The cured film having the spectral characteristic (2) can be formed using the composition according to the embodiment of the present invention including an infrared absorber in addition to a coloring material which shields visible light. The infrared absorber is preferably a compound having a maximum absorption wavelength in a wavelength range of 800 nm or more and less than 900 nm. Further, by incorporating a chromatic colorant in the composition, the spectrum of the above (2) is easily adjusted to be in a preferable range.

The cured film having the spectral characteristic (3) can be formed using the composition according to the embodiment of the present invention including an infrared absorber in addition to a coloring material which shields visible light. The infrared absorber is preferably a compound having a maximum absorption wavelength in a wavelength range of 900 nm or more and less than 1000 nm. Further, by incorporating a chromatic colorant and a compound having a maximum absorption wavelength in a wavelength range of 800 nm or more and less than 900 nm in the composition, the spectrum of the above (3) is easily adjusted to be in a preferable range.

The thickness of the cured film is not particularly limited and is preferably 0.1 to 20 μm and more preferably 0.5 to 10 μm.

<Kit>

Next, a kit according to an embodiment of the present invention will be described.

The kit according to the embodiment of the present invention has the above-described composition according to the embodiment of the present invention (dry etching composition), an infrared absorbing composition for photolithography including an infrared absorber.

As the infrared absorber in the infrared absorbing composition for photolithography, the infrared absorbers described in the above-described composition according to the embodiment of the present invention can be used. The infrared absorbing composition for photolithography preferably includes a radical polymerizable compound and a photopolymerization initiator. Examples of the radical polymerizable compound include the compounds described in the above-described section of the compound having a group having an ethylenically unsaturated bond in the composition according to the embodiment of the present invention. As the photopolymerization initiator, the photopolymerization initiators described in the above-described composition according to the embodiment of the present invention can be used. In addition, the infrared absorbing composition for photolithography preferably includes a resin having an acid group. As the resin having an acid group, the resins having an acid group described in the above composition according to the embodiment of the present invention can be preferably used. In addition, it is preferable that the infrared absorbing composition for photolithography does not contain a coloring material which shields visible light.

<Pattern Formation Method and Method of Manufacturing Optical Filter>

A pattern formation method according to an embodiment of the present invention includes a step of forming a composition layer on a support using the above-described composition according to the embodiment of the present invention (dry etching composition), and a step of patterning the composition layer by a dry etching method. The composition according to the embodiment of the present invention has high visible light shielding properties and excellent transmittance of infrared rays in a specific wavelength range. Therefore, according to the pattern formation method according to the embodiment of the present invention, it is possible to form a pattern (a pixel pattern of an infrared transmitting filter) having high visible light shielding properties and excellent transmittance of infrared rays in a specific wavelength range with high resolution.

It is preferable that the pattern formation method according to the embodiment of the present invention further includes a step of forming an infrared absorbing composition layer on the support using an infrared absorbing composition including an infrared absorber after patterning the composition layer by the dry etching method, and a step of patterning the infrared absorbing composition layer by photolithography. According to this embodiment, it is possible to form a pattern of a cured film (a pixel pattern of an infrared transmitting filter) using the composition according to the embodiment of the present invention and a pattern of a cured film (a pixel pattern of an infrared cut filter) using the infrared absorbing composition on the support. For example, it is possible to form the pixel pattern of the infrared cut filter with good resolution in a part in which the pixel pattern of the infrared transmitting filter is missed. As the infrared absorbing composition, the infrared absorbing compositions for photolithography described in the above-described section of the kit of the present invention can be used.

It is preferable that the pattern formation method according to the embodiment of the present invention further includes a step of forming a coloring composition layer on the infrared absorbing composition layer using a coloring composition including a chromatic colorant after patterning the infrared absorbing composition layer by photolithography, and a step of patterning the coloring composition layer by photolithography. As the chromatic colorant, the chromatic colorants described in the section of the composition according to the embodiment of the present invention can be used. The coloring composition preferably includes a radical polymerizable compound and a photopolymerization initiator. According to this embodiment, a laminate in which a pattern of a cured film (a pixel pattern of a color filter) formed using the coloring composition is formed on the infrared cut filter can be manufactured.

In addition, a method of manufacturing an optical filter according to an embodiment of the present invention includes the above-described pattern formation method according to the embodiment of the present invention. The optical filter obtained by the method of manufacturing an optical filter according to an embodiment of the present invention may have only the pattern of the cured film formed using the composition according to the embodiment of the present invention (the pixel pattern of the infrared transmitting filter) and may further have the pattern of the cured film (the pixel pattern of the infrared cut filter) formed using the infrared absorbing composition. Further, the optical filter may have the pattern of the cured film (the pixel pattern of the color filter) formed using the coloring composition. Hereinafter, the pattern formation method according to the embodiment of the present invention will be described in detail.

In the pattern formation method according to the embodiment of the present invention, a composition layer is formed on a support using the above-described composition according to the embodiment of the present invention. Examples of the support include substrates formed of materials such as silicon, non-alkali glass, soda glass, PYREX (registered trademark) glass, and quartz glass. A charge coupled device (CCD), a complementary metal-oxidesemiconductor (CMOS), a transparent conductive film, or the like may be formed on the support. In addition, a black matrix may be formed on the support to separate each pixel pattern from each other. If necessary, an undercoat layer may be provided on the support to improve adhesiveness with a layer above the support, to prevent diffusion of materials, or to make a surface of the substrate flat.

As a method of applying the composition according to the embodiment of the present invention to the support, a known method can be used. Examples thereof include a dropwise addition method (drop cast); a slit coating method; a spray method; a roll coating method; a spin coating method (spin coating); a casting coating method; a slit and spin method; a prewetting method (for example, a method described in JP2009-145395A); various printing methods such as jetting system printing such as ink jet (for example, an on-demand method, a piezo method, and a thermal method), and nozzle jet, flexographic printing, screen printing, gravure printing, reverse offset printing, and metal mask printing method; a transfer method using a metal mold or the like; and a nanoimprint method. The application method in ink jet is not particularly limited and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A.

The composition layer formed on the support may be dried (pre-baked). The pre-baking temperature is preferably 150° C. or lower, more preferably 120° C. or lower, and even more preferably 110° C. or lower. The lower limit can be set to, for example, 50° C. or higher or 80° C. or higher. The pre-baking time is preferably 10 to 3000 seconds, more preferably 40 to 2500 seconds, and even more preferably 80 to 2200 seconds. The drying can be performed using a hot plate, an oven, or the like.

Next, the composition layer formed on the support is patterned by a dry etching method. Specifically, the composition layer formed on the support is cured and the cured material layer (infrared transmitting layer) is formed. Then, a photoresist layer is formed on the cured material layer (infrared transmitting layer). Next, the photoresist layer is patterned to form a resist pattern. Next, the cured material layer (infrared transmitting layer) is dry-etched using the resist pattern as an etching mask, and the resist pattern remaining after the dry etching is removed to performing patterning of the composition layer.

As a curing method of the composition layer, a heat treatment is preferable. According to this embodiment, the entire composition layer can be substantially uniformly cured. The heating temperature is preferably 150° C. to 240° C., more preferably 180° C. to 230° C., and even more preferably 195° C. to 225° C. The heating time is preferably 250 to 600 seconds, more preferably 250 to 500 seconds, and even more preferably 280 to 480 seconds.

For forming the photoresist layer, for example, a positive type radiation-sensitive composition is used. As the positive type radiation-sensitive composition, radiation-sensitive composition sensitive to radiations such as a radiation-sensitive composition sensitive to ultraviolet rays (g-rays, h-rays, and i-rays), far-ultraviolet rays including excimer lasers, electron beams, ion beams, and X-rays can be used. Among these radiations, g-rays, h-rays, and i-rays are preferable, and among these rays, i-rays are more preferable. Specifically, as the positive type radiation-sensitive composition, a composition that contains a quinone diazide compound and an alkali-soluble resin is preferably used. The positive type radiation-sensitive composition containing a quinone diazide compound and an alkali-soluble resin is used as a positive type photoresist by using a phenomenon in which a quinon diazide group is decomposed by irradiation of light having a wavelength of 500 nm or less so as to generate a carboxyl group, so that the composition is changed from the alkali-non-soluble state to the alkali-soluble state. As the quinone diazide compound, there is a naphto quinone diazide compound.

The thickness of the photoresist layer is preferably 0.1 to 3 μm, more preferably 0.2 to 2.5 μm, and even more preferably 0.3 to 2 μm.

The patterning of the photoresist layer can be performed by exposing the photoresist layer through a predetermined mask pattern and developing the photoresist layer after the exposure with a developer.

As the developer, any developer can be preferably used as long as the developer has no influence on the cured material layer (infrared transmitting layer) formed of the composition according to the embodiment of the present invention as a base or the like and is capable of dissolving and removing an uncured portion of the photoresist layer. For example, an organic solvent or an alkaline aqueous solution can be used. As the alkaline aqueous solution, an alkaline aqueous solution obtained by dissolving an alkaline compound such that the concentration of the alkaline compound is 0.001% to 10% by mass and preferably 0.01% to 5% by mass is suitably used. Examples of the alkaline compound include organic alkaline compounds such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In addition, in a case of using the alkaline aqueous solution as a developer, generally, a washing treatment with water is performed after development.

Using the resist pattern formed in this manner as an etching mask, the cured material layer (infrared transmitting layer) is dry-etched. As dry etching, it is preferable to perform dry etching in the following manner from the viewpoint of forming a pattern cross section to have a shape closer to a rectangle and from the viewpoint of further reducing damage to the support.

An embodiment is preferable which includes a first stage etching of etching up to an area (depth) with no support exposed by using a mixed gas of fluorine-based gas and oxygen gas (O₂), a second stage etching of preferably etching up to the vicinity of an area (depth) with the support exposed by using a mixed gas of nitrogen gas (N₂) and oxygen gas (O₂) after the first stage etching, and an over-etching performed after the support is exposed. Hereinafter, a specific method of dry etching, the first stage etching, the second stage etching, and the over-etching will be described.

The dry etching is preferably performed while previously obtaining the etching conditions in the following manner.

(1) The etching rate (nm/min) in the first stage etching and the etching rate (nm/min) in the second stage etching are each calculated.

(2) The time for etching a desired thickness in the first stage etching and the time for etching a desired thickness in the second stage etching are each calculated.

(3) The first stage etching is performed according to the etching time calculated in (2).

(4) The second stage etching is performed according to with the etching time calculated in (2). Alternatively, the etching time is determined by endpoint detection, and the second stage etching may be performed according to the determined etching time.

(5) The over-etching time is calculated with respect to the total time of (3) and (4), and the over-etching is performed.

The mixed gas used in the first stage etching step preferably includes a fluorine-based gas and an oxygen gas (O₂) from the viewpoint of processing a cured material layer (infrared transmitting layer) formed of the composition according to the embodiment of the present invention into a rectangle shape. The first stage etching step may avoid damage to the support by adopting an embodiment of etching up to an area with no support exposed.

In addition, after the etching is performed up to an area with no support exposed by the mixed gas of fluorine-based gas and oxygen gas in the first stage etching step, an etching treatment in the second stage etching step and an etching treatment in the over-etching step may be performed using the mixed gas of nitrogen gas and oxygen gas from the viewpoint of avoiding damage to the support.

The ratio between the etching amount in the first stage etching step and the etching amount in the second stage etching step is preferably determined without deteriorating rectangularity by etching treatment in the first stage etching step. The ratio of the etching amount in the second stage etching step in the total etching amount (the total sum of the etching amount in the first stage etching step and the etching amount in the second stage etching step) is preferably a range of more than 0% and 50% or less, more preferably 10 to 20%. Here, the etching amount indicates the film thickness at which the cured material layer (infrared transmitting layer) remains.

In addition, it is preferable that the dry etching includes an over-etching treatment. It is preferable that the over-etching rate is set and the over-etching treatment is performed. In addition, the over-etching rate is preferably calculated from the time of the etching treatment initially performed. The over-etching rate can be set randomly, but from the viewpoint of the etching resistance of the photoresist and maintainability of rectangularity of the etched pattern, the over-etching rate is preferably 30% or less, more preferably 5% to 25%, and particularly preferably 10% to 15% of the etching treatment time in the etching step.

Next, a resist pattern (that is, an etching mask) which remains after the dry etching is removed. The removal of the resist pattern preferably includes a step of applying a stripping liquid or a solvent to the resist pattern to make the resist pattern ready for removal, and a step of removing the resist pattern using cleaning water. For a method of removing the resist pattern, the description of paragraphs 0318 to 0324 of JP2013-054080A can be referred to and the content thereof is incorporated in this specification.

In the pattern formation method according to the embodiment of the present invention, it is preferable that after the composition layer is patterned by the dry etching method, an infrared absorbing composition layer is formed on the support and then the infrared absorbing composition layer is patterned by photolithography.

In the formation of the infrared absorbing composition layer, as an application method of the infrared absorbing composition, the application method of the above-described composition according to the embodiment of the present invention can be used. The infrared absorbing composition layer may be dried (pre-baked). The pre-baking temperature is preferably 150° C. or lower, more preferably 120° C. or lower, and even more preferably 110° C. or lower. The lower limit can be set to, for example, 50° C. or higher or 80° C. or higher. The pre-baking time is preferably 10 to 3000 seconds, more preferably 40 to 2500 seconds, and even more preferably 80 to 2200 seconds. The drying can be performed using a hot plate, an oven, or the like.

It is preferable that the patterning in the photolithography includes a step of exposing the infrared absorbing composition layer in a pattern shape, and a step of developing and removing an unexposed portion of the infrared absorbing composition layer after the exposure to form a pattern.

For example, by exposing the infrared absorbing composition layer through a mask having a predetermined pattern using an exposure device such as a stepper, the infrared absorbing composition layer can be exposed in a pattern shape. As the radiation (light) that can be used during the exposure, ultraviolet rays such as g-rays and i-rays are preferably used (i-rays are particularly preferably used). The irradiation amount (exposure amount) is, for example, preferably 0.03 to 2.5 J/cm², more preferably 0.05 to 1.0 J/cm², and most preferably 0.08 to 0.5 J/cm². The oxygen concentration at the time of exposure can be appropriately selected. In addition to exposure the atmosphere, the exposure may be performed in a low oxygen atmosphere having an oxygen concentration of, for example, 19% by volume or lower (preferably 15% by volume or lower, more preferably 5% by volume or lower, and even more preferably substantially 0% by volume), or the exposure may be performed in a high oxygen atmosphere having an oxygen concentration of higher than 21% by volume (preferably 22% by volume or higher, more preferably 30% by volume or higher, and even more preferably 50% by volume or higher). The exposure illuminance can be appropriately set, and the exposure illuminance can be generally selected from a range of 1000 W/m² to 100000 W/m² (preferably 5000 W/m² or higher, more preferably 15000 W/m² or higher, and even more preferably 35000 W/m² or higher). Appropriate conditions of the oxygen concentration and the exposure illuminance may be combined. For example, the oxygen concentration and the exposure illuminance can be set to an oxygen concentration of 10% by volume and an illuminance of 10,000 W/m² or can be set to an oxygen concentration of 35% by volume and an illuminance of 20000 W/m².

Next, a pattern is formed by developing and removing an unexposed portion of the infrared absorbing composition layer. The unexposed portion can be developed and removed using a developer. As a result, the unexposed portion of the infrared absorbing composition layer in the exposure step is eluted into the developer, and only the photocured portion remains on the support. As the developer, an alkali developer which does not cause damages to a solid-state imaging element as a base, a circuit or the like is desired. For example, the temperature of the developer is preferably 20° C. to 30° C. The developing time is preferably 20 to 180 seconds. In addition, in order to further improve residue removing properties, a step of shaking the developer per 60 seconds and supplying a new developer may be repeated multiple times.

Examples of an alkaline agent used in the developer include an organic alkaline compound such as ammonia water, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. As the developer, an alkaline aqueous solution is preferably used in which the above alkaline agent is diluted with pure water. The concentration of the alkaline agent in the alkaline aqueous solution is preferably 0.001% to 10% by mass and more preferably 0.01% to 1% by mass. In addition, a surfactant may be used as the developer. Examples of the surfactant include the surfactants described above in the composition, and a nonionic surfactant is preferable. In a case where the developer including the alkaline aqueous solution is used, it is preferable that the film is rinsed with pure water after development.

In the present invention, after drying is performed after the development step, a heat treatment (post-baking) or a curing step of curing the film by post-exposure may be performed.

The post-baking is a heat treatment which is performed after development to complete curing. For example, the heating temperature in the post-baking is preferably 100° C. to 240° C. and more preferably 200° C. to 240° C. In addition, in a case where an organic electroluminescence (organic EL) element is used as a light-emitting light source, or in a case where a photoelectric conversion film of an image sensor is formed of an organic material, the heating temperature is preferably 150° C. or lower, more preferably 120° C. or lower, even more preferably 100° C. or lower, and even still more preferably 90° C. or lower. The lower limit can be set to, for example, 50° C. or higher. The film after the development can be post-baked continuously or batchwise using heating means such as a hot plate, a convection oven (hot air circulation dryer), a high frequency heater under the above conditions.

For the post-exposure, for example, g-rays, h-rays, i-rays, excimer lasers such as KrF or ArF, electron beams, or X-rays can be used. It is preferable that the post-exposure is performed using an existing high pressure mercury lamp at a low temperature of about 20° C. to 50° C., and the irradiation time is 10 seconds to 180 seconds and preferably 30 seconds to 60 seconds. In a case where post-exposure and post-heating are performed in combination, it is preferable that post-exposure is performed before post-heating.

In the pattern formation method according to the embodiment of the present invention, it is preferable that after the infrared absorbing composition layer is patterned by the photolithography, a coloring composition layer is formed on the patterned infrared absorbing composition layer using a coloring composition including a chromatic colorant and then the coloring composition layer is patterned by photolithography. Regarding the method of forming the coloring composition layer and the patterning by photolithography, the above-described methods may be used.

<Solid-State Imaging Element>

The composition according to the embodiment of the present invention can be used for a solid-state imaging element. The configuration of the solid-state imaging element is not particularly limited as long as it functions as a solid-state imaging element. For example, the following configuration can be adopted.

The solid-state imaging element includes a plurality of photodiodes and transfers electrodes on the support, the photodiodes constituting a light receiving area of the solid-state imaging element (for example, a CCD image sensor or a CMOS image sensor), and the transfer electrode being formed of polysilicon or the like. In the solid-state imaging element, a light shielding film which is formed of tungsten or the like and has openings in only light receiving portions of the photodiodes is provided on the photodiodes and the transfer electrodes, a device protective film formed of silicon nitride or the like is formed on the light shielding film so as to cover the entire surface of the light shielding film and the light receiving portions of the photodiodes, and the cured film formed using the composition according to the embodiment of the present invention is formed on the device protective film. Further, a configuration in which light collecting means (for example, a microlens; hereinafter, the same shall be applied) is provided on the device protective film and below the cured film formed using the composition according to the embodiment of the present invention (on a side thereof close to the support), or a configuration in which light collecting means is provided on the cured film formed using the composition according to the embodiment of the present invention may be adopted.

<Infrared Sensor>

The composition according to the embodiment of the present invention can be used for an infrared sensor. The configuration of the infrared sensor is not particularly limited as long it functions as an infrared sensor.

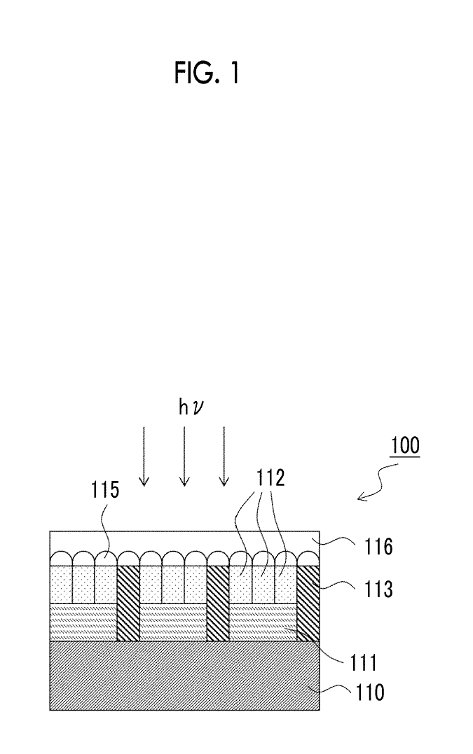

Hereinafter, an embodiment of an infrared sensor according to the present invention will be described using FIG. 1.

In an infrared sensor 100 shown in FIG. 1, reference numeral 110 represents a solid-state imaging element.

In an imaging area provided on the solid-state imaging element 110, infrared cut filters 111 and color filters 112 are provided.

The infrared cut filters 111 are configured to allow transmission of light in the visible range (for example, light having a wavelength of 400 to 700 nm) and to shield light in the infrared range (for example, at least part of light having a wavelength of 800 to 1300 nm, preferably at least part of light having a wavelength of 900 to 1200 nm, and more preferably at least part of light having a wavelength of 900 to 1000 nm).

In the color filters 112, pixel patterns which allow transmission of light having a specific wavelength in the visible range and absorb the light are formed. For example, filters in which pixel patterns of red (R), green (G), and blue (B) are formed are used.

Infrared transmitting filters 113 shield visible light, allow transmission of an infrared ray having a specific wavelength, and are formed of the cured film formed using the composition according to the embodiment of the present invention.

Microlenses 115 are disposed on an incidence ray hν side of the color filters 112 and the infrared transmitting filters 113. A planarizing layer 116 is formed so as to cover the microlenses 115.

In the embodiment shown in FIG. 1, the thickness of the color filters 112 is the same as the thickness of the infrared transmitting filters 113. However, the thickness of the color filters 112 may be different from the thickness of the infrared transmitting filters 113.

In addition, in the embodiment shown in FIG. 1, the color filters 112 are provided on the incidence ray hν side compared to the infrared cut filters 111. The order of the infrared cut filters 111 and the color filters 112 may be reversed, and the infrared cut filters 111 may be provided on the incidence ray hν side compared to the color filters 112.

In addition, in the embodiment shown in FIG. 1, the infrared cut filters 111 and the color filters 112 are laminated adjacent to each other. However, the infrared cut filters and the color filters are not necessarily provided adjacent to each other, and another layer may be provided therebetween.

According to this infrared sensor, image information can be acquired in real time. Therefore, the infrared sensor can be used for motion sensing in a case where a motion detecting target is recognized. Further, since distance information can be acquired, for example, an image including 3D information can be captured.

### EXAMPLES

Hereinafter, the present invention will be described in more detail using examples. However, the present invention is not limited to the following examples as long as it does not depart from the scope of the present invention. Unless specified otherwise, “part(s)” and “%” represent “part(s) by mass” and “% by mass %”.

<Preparation of Pigment Dispersion Liquid>

Components shown in the table below were mixed and dispersed using a beads mill for 15 hours to prepare pigment dispersion liquids 1 to 5.

TABLE 1

| | Pigment | | Resin | | | | Solvent | |
|---|---|---|---|---|---|---|---|---|
| | Kind | % by mass | Kind | % by mass | Kind | % by mass | Kind | % by mass |
| Pigment dispersion | PR254 | 13.5 | Resin 2 | 2 | Resin 5 | 2 | PGMEA | 82.5 |
| liquid 1 | | | | | | | | |
| Pigment dispersion | PB15:6 | 13.5 | Resin 3 | 2 | Resin 6 | 2 | PGMEA | 82.5 |
| liquid 2 | | | | | | | | |
| Pigment dispersion | PY139 | 14.8 | Resin 1 | 3 | Resin 5 | 2.2 | PGMEA | 80 |
| liquid 3 | | | | | | | | |
| Pigment dispersion | PV23 | 14.8 | Resin 1 | 3 | Resin 5 | 2.2 | PGMEA | 80 |
| liquid 4 | | | | | | | | |
| Pigment dispersion | PG36 | 14.8 | Resin 4 | 5.2 | | | PGMEA | 80 |
| liquid 5 | | | | | | | | |

(Pigment)
PR254: C.I. Pigment Red 254
PB15:6: C.I. Pigment Blue 15:6
PY139: C.I. Pigment Yellow 139
PV23: C.I. Pigment Violet 23
PG36: C.I. Pigment Green 36

(Resin)

In the resins shown below, the numerical value attached to the main chain is the molar ratio, and the numeral value attached to the side chain is the number of repeating units. For the crosslinkable group value in the resin 5, the ethylenically unsaturated bond group value was calculated as the crosslinkable group value.
Resin 1: Disperbyk-111 (manufactured by BYK Chemie GmbH)
Resin 2: the following structure (Mw: 7950, acid value=0.6 mmol/g)

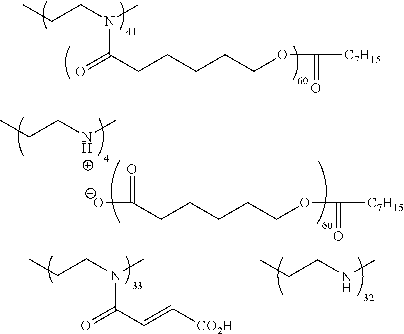

Resin 3: the following structure (Mw: 30000, acid value=1.0 mmol/g)

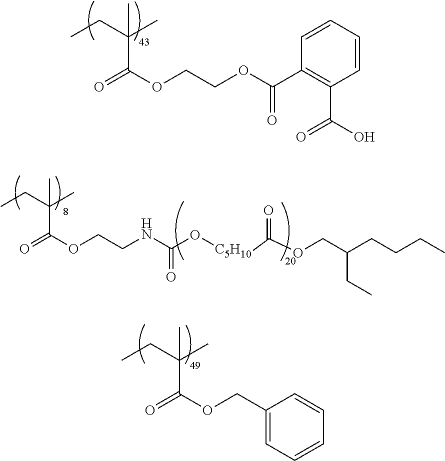

Resin 4: the following structure (Mw: 24000, acid value=0.9 mmol/g)

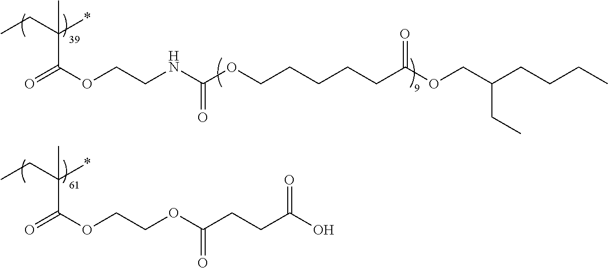

Resin 5: the following structure (Mw: 12000, acid value=0.6 mmol/g, crosslinkable group value=1.4 mmol/g)

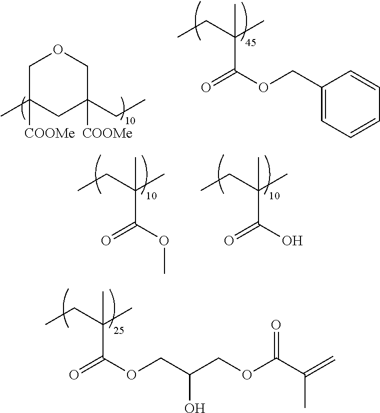

Resin 6: the following structure (Mw: 19000, acid value=1.4 mmol/g)

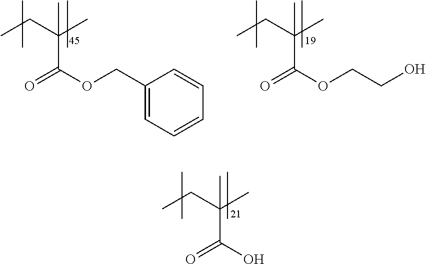

(Solvent)
PGMEA: propylene glycol monomethyl ether acetate

<Preparation of Composition>

Raw materials shown in the table below were mixed to prepare each composition.

TABLE 2

| | Exam- | Exam- | Exam- | Exam- | Exam- |
|---|---|---|---|---|---|
| | ple 1 | ple 2 | ple 3 | ple 4 | ple 5 |
| Pigment dispersion | 28 | 28 | 28 | 18 | 40 |
| liquid 1 | | | | | |
| Pigment dispersion | 38 | 38 | 38 | 47 | 40 |
| liquid 2 | | | | | |
| Pigment dispersion | 15 | 15 | 15 | 23 | 20 |
| liquid 3 | | | | | |
| Pigment dispersion | 5 | 5 | 5 | 13 | |
| liquid 4 | | | | | |
| Pigment dispersion | 10 | 10 | 10 | | |
| liquid 5 | | | | | |
| Crosslinkable | 0.4 | | | | |
| compound 1 | | | | | |
| Crosslinkable | | 0.4 | | | |
| compound 2 | | | | | |
| Crosslinkable | | | 0.4 | 0.4 | 0.4 |
| compound 3 | | | | | |

Crosslinkable compound 1: KAYARAD DPHA (manufactured by Nippon Kayaku Co., Ltd., a compound having a group having an ethylenically unsaturated bond, crosslinkable group value=10.1 mmol/g)
Crosslinkable compound 2: tetraethoxysilane (crosslinkable group value=26.3 mmol/g)
Crosslinkable compound 3: EHPE3150 (manufactured by Daicel Corporation, epoxy resin, crosslinkable group value=5.6 mmol/g)

Regarding the crosslinkable compound 1, the ethylenically unsaturated bond group value was calculated as the crosslinkable group value. Regarding the crosslinkable compound 2, the Si value was calculated as the crosslinkable group value. Regarding the crosslinkable compound 3, the epoxy group value was calculated as the crosslinkable group value.

<Measurement of Light Absorbance>

Each of the above compositions was applied to a glass wafer by spin coating such that the film thickness after post-baking was 0.85 μm, and was dried and heated at 100° C. for 120 seconds using a hot plate. After the film was dried, further, the film was heated (post-baked) at 220° C. for 300 seconds using a hot plate to form a cured film. With respect to the glass wafer having the cured film formed thereon, the transmittance in a wavelength range of 300 to 1300 nm, the minimum value A of the light absorbance in a wavelength range of 400 to 700 nm, and the maximum value B of the light absorbance in a wavelength range of 1100 to 1300 nm were measured using an ultraviolet-visible-near-infrared spectrophotometer (U-4100, manufactured by Hitachi High-Technologies Corporation).

<Pattern Formation Method (Manufacturing of Infrared Transmitting Filter)>

Each of the above compositions was applied to a glass wafer by a spin coater and then dried at 100° C. for 120 seconds using a hot plate. Next, a cured material layer (infrared transmitting layer) was formed by performing a heat treatment at 220° C. for 300 seconds using a hot plate. The film thickness of the infrared transmitting layer was 0.85 μm.

Next, a positive photoresist “FHi622BC” (manufactured by FUJIFILM Electronic Materials Co., Ltd.) was applied to the infrared transmitting layer and prebaking was performed at 110° C. for 1 minute to form a photoresist layer having a film thickness of 1.4 μm.

Subsequently, the photoresist layer was subjected to pattern exposure at an exposure amount of 200 mJ/cm² using an i-ray stepper (manufactured by Canon Inc.) and a heat treatment was performed on the photoresist layer at a photoresist layer temperature or an atmospheric temperature of 90° C. for 1 minute. Then, a development treatment was performed for 1 minute by using a developer “FHD-5” (manufactured by FUJIFILM Electronic Materials Co., Ltd.), and a post-bake treatment was further performed at a temperature of 110° C. for 1 hour to form a resist pattern. This resist pattern was a pattern in which square resist films formed with a length of one side of 1.1 μm were arranged in a pane pattern in consideration of an etching conversion difference (contraction of the pattern width by etching).

Next, the dry etching of the infrared transmitting layer using the resist pattern as an etching mask was performed in the following procedure.

The first etching treatment was performed for 120 seconds with a dry etching device (U-621, manufactured by Hitachi High-Technologies Corporation) under the conditions of RF (high frequency) power: 800 W, antenna bias: 400 W, wafer bias: 200 W, internal pressure of chamber: 4.0 Pa, substrate temperature: 50° C., and gas kind and flow rate of mixed gas: CF₄: 80 mL/min, O₂: 40 mL/min, and Ar: 800 mL/min.

The scraped amount of the infrared transmitting layer under the etching conditions was 830 nm and the residual film of the infrared transmitting layer was about 20 nm.

Next, the second stage etching treatment was performed with the same etching chamber under the conditions of RF power: 600 W, antenna bias: 100 W, wafer bias: 250 W, internal pressure of chamber: 2.0 Pa, substrate temperature: 50° C., and gas kind and flow rate of mixed gas: N₂: 500 mL/min, O₂: 50 mL/min, and Ar: 500 mL/min (N₂/O₂/Ar=10/1/10).

The etching rate of the infrared transmitting layer under the conditions of the second stage etching was 60 nm/min or more and it took approximately 40 seconds to etch the residual film of the infrared transmitting layer.

After performing the dry etching under the above-described conditions, a stripping treatment was performed for 120 seconds by using a photoresist stripping liquid “MS600-50” (manufactured by FUJIFILM Electronic Materials Co., Ltd.) to remove the photoresist pattern.

Further, washing with pure water and spin dry were performed. Thereafter, a dehydration baking treatment was performed at 100° C. for 2 minutes. Thus, a pattern in which square pixels having a length of one side of 1.0 μm were arranged in a pane pattern was formed, and an infrared transmitting filter was manufactured.

<Evaluation Method>

<<Pattern Resolution (Pattern Formability)>>

The pattern shape was evaluated according to the following standards.

3: A clear square shape can be recognized.

2: A square shape can be recognized.

1: The shape is collapsed.

<Spectroscopic Recognition>

The obtained infrared transmitting filter was incorporated in the solid-state imaging element. The obtained solid-state imaging element was irradiated with a near-infrared light emitting diode (LED) light source having a light emitting wavelength of 940 nm under the environment of low illuminance (0.001 Lux), images were captured, and image performance was compared and evaluated. The evaluation standards were as below.

3: An object can be clearly recognized on the image.

2: An object can be recognized on the image.

1: An object cannot be recognized on the image.

TABLE 3

| | A/B | Pattern resolution | Spectroscopic recognition |
|---|---|---|---|
| Example 1 | 7 | 2 | 3 |
| Example 2 | 7 | 2 | 3 |
| Example 3 | 7 | 3 | 3 |
| Example 4 | 7 | 3 | 3 |
| Example 5 | 5 | 3 | 2 |

From the above results, in Examples in which the pattern was formed by a dry etching method, the pattern of the cured film having high visible light shielding properties and excellent transmittance of infrared rays in a specific wavelength range could be formed with good resolution. In addition, in each Example, the pattern resolution was particularly excellent compared to a case where the pattern was formed by photolithography.

Even in a case where the following compound Q-3, compound S-6, or compound 0-4 is further formulated as an infrared absorber in the compositions of Examples, the same effect can be obtained.

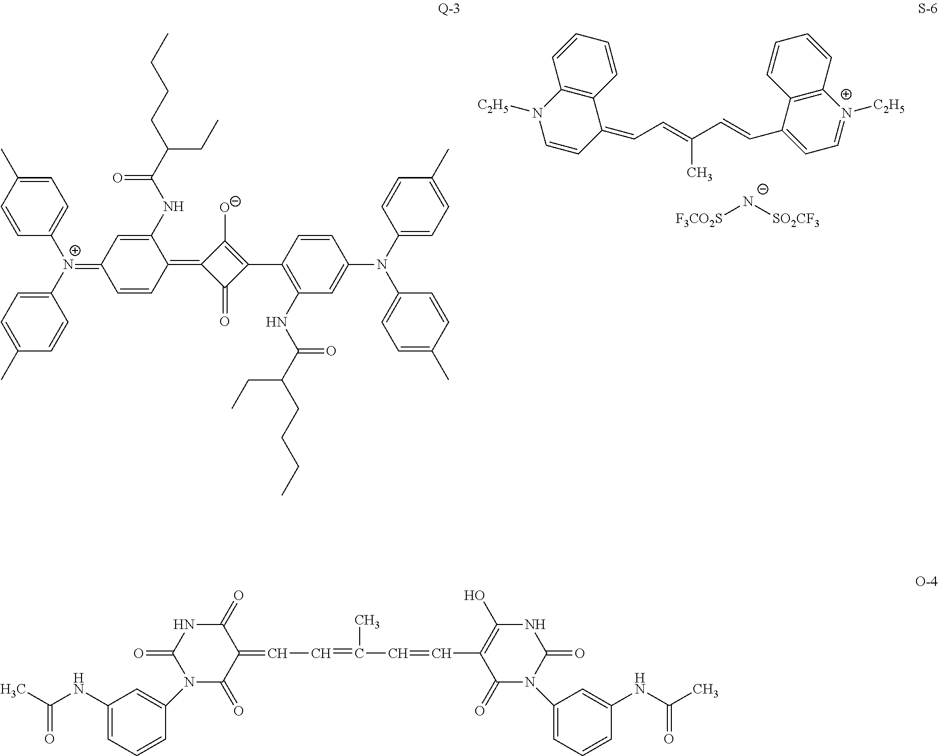

### Example 100

The composition of Example 1 was applied to a silicon wafer by a spin coating method. Thereafter, heating was performed at 100° C. for 2 minutes using a hot plate to form a cured material layer (infrared transmitting layer) of 1.7 μm. Next, a 2 μm square island pattern (infrared transmitting filter) was formed on the infrared transmitting layer using a dry etching method.

Next, the infrared absorbing composition was applied using a spin coating method such that the film thickness after post-baking was 0.85 μm. Next, heating was performed at 100° C. for 2 minutes using a hot plate. Next, areas other than the aforementioned infrared transmitting layer were exposed through a mask using an i-ray stepper exposure device FPA-3000i5+(manufactured by Canon Inc.) at an exposure amount of 1000 mJ/cm². Next, paddle development was performed at 23° C. for 60 seconds using a 0.3% by mass tetramethylammonium hydroxide (TMAH) aqueous solution. Thereafter, the silicon wafer was rinsed with a spin shower and then washed with pure water. Next, heating was performed (post-baked) at 200° C. for 5 minutes using a hot plate to form a pattern (infrared cut filter).

Next, a Red composition was applied to the infrared cut filter by a spin coating method such that the film thickness after post-baking was 0.85 μm. Next, heating was performed at 100° C. for 2 minutes using a hot plate. Next, exposure was performed through a mask having a 2 μm square Bayer pattern using an i-ray stepper exposure device FPA-3000i5+(manufactured by Canon Inc.) at an exposure amount of 1000 mJ/cm². Next, paddle development was performed at 23° C. for 60 seconds using a 0.3% by mass tetramethylammonium hydroxide (TMAH) aqueous solution. Thereafter, the silicon wafer was rinsed with a spin shower and then washed with pure water. Next, by performing (post-baking) heating at 200° C. for 5 minutes using a hot plate, the Red composition was patterned on the infrared cut filter. In the same manner, a Green composition and a Blue composition were sequentially patterned to form red, green, and blue colored patterns.

The optical filter manufactured as described above was incorporated in a solid-state imaging element according to a known method.

The obtained solid-state imaging element was irradiated with an infrared light emitting diode (LED) light source in a low illuminance environment (0.001 Lux) and images were acquired to evaluate image performance. An object could be clearly recognized on the image.

The Red composition, the Green composition, the Blue composition, and the infrared absorbing composition used in Example 100 are as follows.

(Infrared Absorbing Composition)
Infrared absorber dispersion liquid: 43.8 parts by mass
Resin 103: 5.5 parts by mass
Polymerizable compound (ARONIX TO-2349, manufactured by Toagosei Co., Ltd.): 3.2 parts by mass
Polymerizable compound (NK ESTER A-TMMT, manufactured by Shin-Nakamura Chemical Co., Ltd.): 3.2 parts by mass
Photopolymerization initiator 101: 1 part by mass
Ultraviolet absorber UV4: 1.6 parts by mass
Surfactant 101: 0.025 parts by mass
Polymerization inhibitor (p-methoxyphenol): 0.003 parts by mass
Coloring inhibitor (ADEKA STAB AO-80 ((manufactured by ADEKA)): 0.2 parts by mass
PGMEA: 41.47 parts by mass

(Red Composition)

The following components were mixed, stirred, and then filtered through a filter (manufactured by Pall Corporation) formed of nylon and having a pore size of 0.45 μm to prepare the Red composition.
Red pigment dispersion liquid: 51.7 parts by mass
Resin 104 (40% by mass PGMEA solution): 0.6 parts by mass
Polymerizable compound 104: 0.6 parts by mass
Photopolymerization initiator 101: 0.3 parts by mass
Surfactant 101: 4.2 parts by mass
PGMEA: 42.6 parts by mass

(Green Composition)

The following components were mixed, stirred, and then filtered through a filter (manufactured by Pall Corporation) formed of nylon and having a pore size of 0.45 μm to prepare the Green composition.
Green pigment dispersion liquid: 73.7 parts by mass
Resin 104 (40% by mass PGMEA solution): 0.3 parts by mass
Polymerizable compound 101: 1.2 parts by mass
Photopolymerization initiator 101: 0.6 parts by mass
Surfactant 101: 4.2 parts by mass
Ultraviolet absorber (UV-503, manufactured by DAITO CHEMICAL CO., LTD.): 0.5 parts by mass
PGMEA: 19.5 parts by mass

(Blue Composition)

The following components were mixed, stirred, and then filtered through a filter (manufactured by Pall Corporation) formed of nylon and having a pore size of 0.45 μm to prepare the Blue composition.
Blue pigment dispersion liquid: 44.9 parts by mass
Resin 104 (40% by mass PGMEA solution): 2.1 parts by mass
Polymerizable compound 101: 1.5 parts by mass
Polymerizable compound 104: 0.7 parts by mass
Photopolymerization initiator 101: 0.8 parts by mass
Surfactant 101: 4.2 parts by mass
PGMEA: 45.8 parts by mass

The raw materials used in the Red composition, the Green composition, the Blue composition, and the infrared absorbing composition are as follows.

Infrared Absorber Dispersion Liquid

To a mixed liquid including 2.5 parts by mass of an infrared absorber A1, 0.5 parts by mass of a pigment derivative B1, 1.8 parts by mass of a dispersant C1, and 79.3 parts by mass of PGMEA, 230 parts by mass of zirconia beads having a diameter of 0.3 mm were added and dispersed for 5 hours using a paint shaker. Thus, the beads were separated by filtration to manufacture the infrared absorber dispersion liquid.
Infrared absorber A1: a compound (A1) having the following structure
Pigment derivative B1: a compound (B1) having the following structure
Dispersant C1: a resin (C1) having the following structure (Mw=20,000, acid value=105 mgKOH/g) (the numerical value attached to the main chain is the molar ratio, and the numeral value attached to the side chain is the number of repeating units).

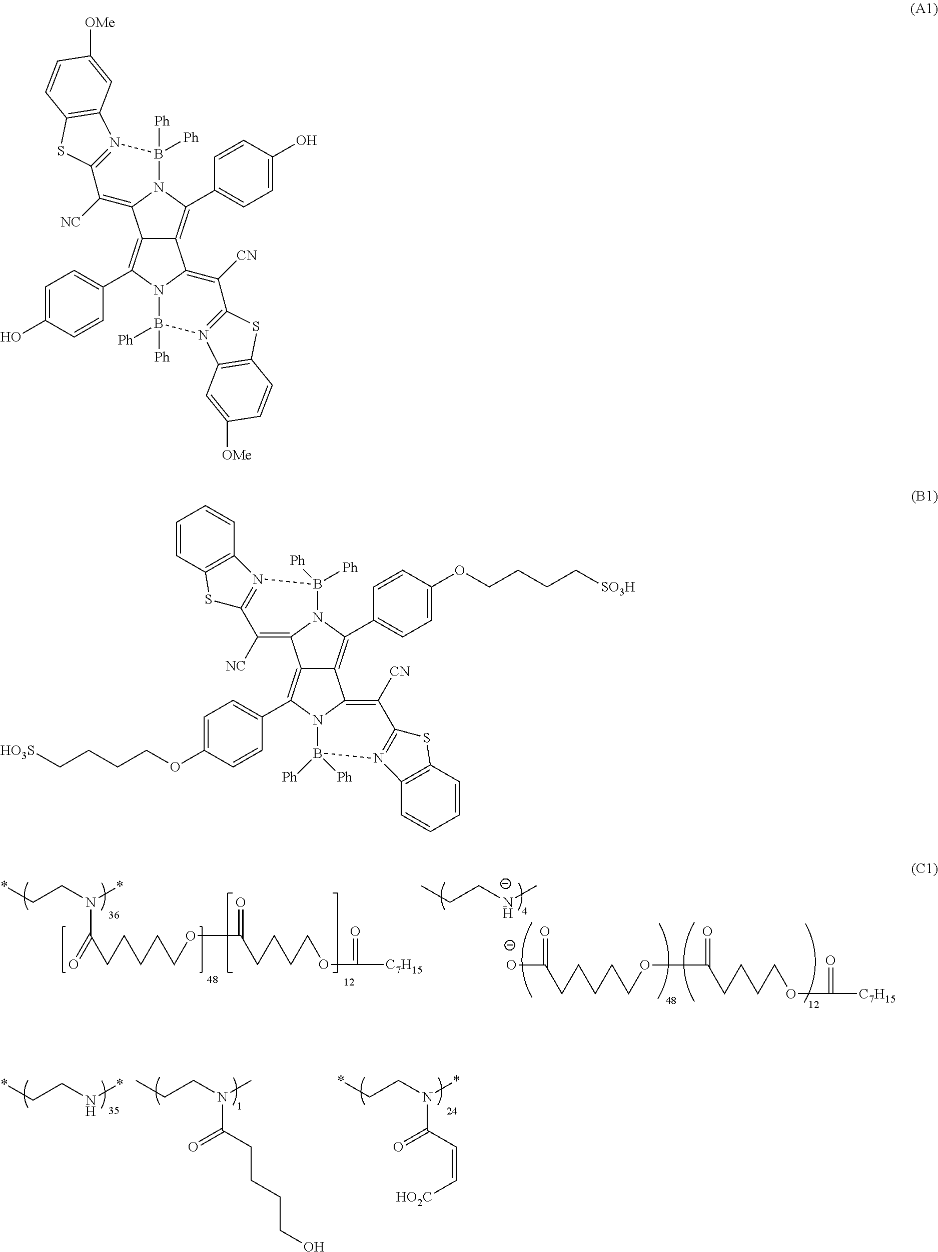

Red Pigment Dispersion Liquid

9.6 parts by mass of C.I. Pigment Red 254 was dispersed in a mixed liquid including 4.3 parts by mass of C.I. Pigment Yellow 139, 6.8 parts by mass of a dispersant (Disperbyk-161, manufactured by BYK Chemie GmbH), and 79.3 parts by mass of PGMEA, while adding 230 parts by mass of zirconia beads having a diameter of 0.3 mm, for 3 hours using a paint shaker. The beads were separated by filtration to manufacture the Red pigment dispersion liquid.

Green Pigment Dispersion Liquid

To a mixed liquid including 6.4 parts by mass of C.I. Pigment Green 36, 5.3 padisperseds by mass of C.I. Pigment Yellow 150, 5.2 parts by mass of a dispersant (Disperbyk-61, manufactured by BYK Chemie GmbH), and 83.1 parts by mass of PGMEA, 230 parts by mass of zirconia beads having a diameter of 0.3 mm were added and dispersed for 3 hours using a paint shaker. The beads were separated by filtration to manufacture the Green pigment dispersion liquid.

Blue Pigment Dispersion Liquid

To a mixed liquid including 9.7 parts by mass of C.I. Pigment Blue 15:6, 2.4 parts by mass of C.I. Pigment Violet 23, 5.5 parts by mass of a dispersant (Disperbyk-161, manufactured by BYK Chemie GmbH), and 82.4 parts by mass of PGMEA, 230 parts by mass of zirconia beads having a diameter of 0.3 mm were added and dispersed for 3 hours using a of zirconia beads having a diameter of 0.3 mm were added and dispersed for 3 hours using a paint shaker. The beads were separated by filtration to manufacture the Blue pigment dispersion liquid.
Polymerizable compound 101: KAYARAD DPHA (manufactured by Nippon Kayaku Co., Ltd.)
Polymerizable compound 104: the following structure

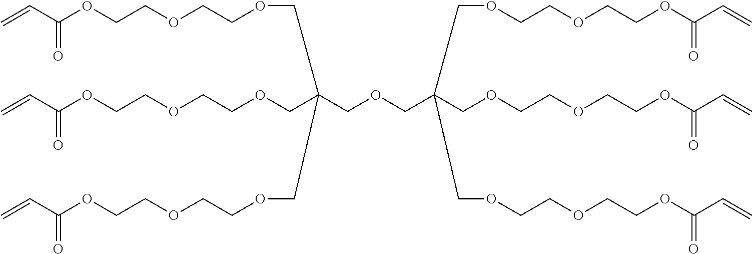 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 103: a resin having the following structure (the numerical value attached to the main chain is the molar ratio; Mw=40,000, acid value=100 mgKOH/g)

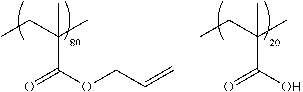

Resin 104: the following structure (Mw=11000, the numerical value attached to the main chain is the molar ratio)

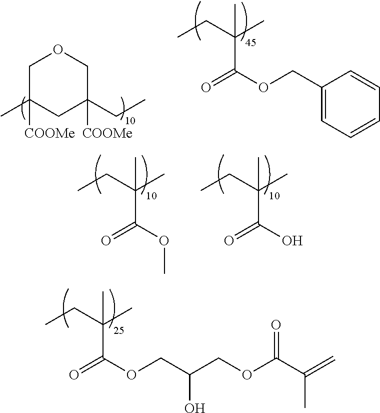

Photopolymerization initiator 101: IRGACURE-OXE01 (manufactured by BASF SE)
Ultraviolet absorber UV4: a compound having the following structure

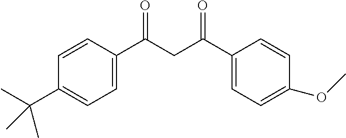 [SMILES: COc1ccc(C(=O)CC(=O)c2ccc(C(C)(C)C)cc2)cc1]

Surfactant 101: 1% by mass of PGMEA solution of the following mixture (Mw=14000). In the following formula, % indicating the proportion of the repeating unit is % by mole.

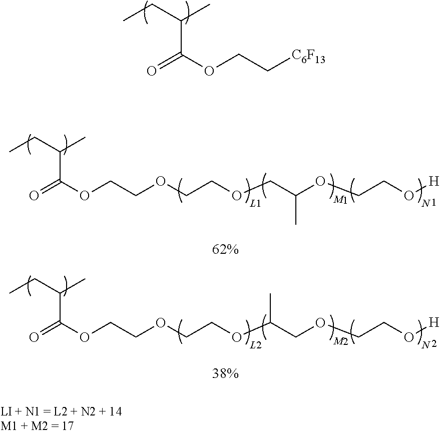

### EXPLANATION OF REFERENCES

100: infrared sensor
110: solid-state imaging element
111: infrared cut filter
112: color filter
113: infrared transmitting filter
115: microlens
116: planarizing layer
hν: incidence ray

What is claimed is:

1. A dry etching composition comprising:
a coloring material which allows transmission of infrared rays and shields visible light;
a curable compound; and
a solvent,
wherein a ratio A/B between a minimum value A of a light absorbance of the composition in a wavelength range of 400 to 700 nm and a maximum value B of a light absorbance in a wavelength range of 1100 to 1300 nm is 4.5 or greater.

2. The dry etching composition according to claim 1,
wherein the curable compound includes a compound having at least one selected from the group consisting of a group having an ethylenically unsaturated bond, an epoxy group, and an alkoxysilyl group.

3. The dry etching composition according to claim 1,
wherein the curable compound includes a compound having an epoxy group.

4. The dry etching composition according to claim 1,
wherein the curable compound includes a resin A,
the resin A includes a resin A1 having a crosslinkable group, and a resin A2 having an acid group, and
a sum of a crosslinkable group value and an acid value of the resin A is 0.1 to 10.0 mmol/g.

5. The dry etching composition according to claim 3,
wherein the curable compound includes a resin A,
the resin A includes a resin A1 having a crosslinkable group, and a resin A2 having an acid group, and
a sum of a crosslinkable group value and an acid value of the resin A is 0.1 to 10.0 mmol/g.

6. The dry etching composition according to claim 4,
wherein the resin A1 is a resin having an epoxy group.

7. The dry etching composition according to claim 5,
wherein the resin A1 is a resin having an epoxy group.

8. The dry etching composition according to claim 6,
wherein an epoxy group value a1 of the resin A1 is 0.1 to 9.9 mmol/g, and an acid value a2 of the resin A2 is 0.1 to 9.9 mmol/g.

9. The dry etching composition according to claim 7,
wherein an epoxy group value a1 of the resin A1 is 0.1 to 9.9 mmol/g, and an acid value a2 of the resin A2 is 0.1 to 9.9 mmol/g.

10. The dry etching composition according to claim 1,
wherein the coloring material which allows transmission of infrared rays and shields visible light includes an organic pigment.

11. The dry etching composition according to claim 1,
wherein the coloring material which allows transmission of infrared rays and shields visible light includes two or more selected from the group consisting of a red pigment, a blue pigment, a yellow pigment, a violet pigment, and a green pigment.

12. A kit comprising:
the dry etching composition according to claim 1; and
an infrared absorbing composition for photolithography including an infrared absorber.

13. A pattern formation method comprising:
forming a composition layer on a support using the dry etching composition according to claim 1; and
patterning the composition layer by a dry etching method.

14. The pattern formation method according to claim 13, further comprising:
forming an infrared absorbing composition layer on the support using an infrared absorbing composition including an infrared absorber after the patterning of the composition layer by the dry etching method; and
patterning the infrared absorbing composition layer by photolithography.

15. The pattern formation method according to claim 14, further comprising:
forming a coloring composition layer on the infrared absorbing composition layer using a coloring composition including a chromatic colorant after the patterning of the infrared absorbing composition layer by photolithography; and
patterning the coloring composition layer by photolithography.

16. A method of manufacturing an optical filter comprising:
the pattern formation method according to claim 13.
